(19) United States
(12) Patent Application Publication
(10) Pub. No.: US 2011/0253313 A1
(43) Pub. Date: Oct. 20, 2011

(54) PLASMA PROCESSING APPARATUS USING TRANSMISSION ELECTRODE

(75) Inventors: Keizo SUZUKI, Kodaira (JP); Ken Takei, Kawasaki (JP); Takehito Usui, Kasumigaura (JP); Masami Kamibayashi, Kokubunji (JP); Nobuyuki Negishi, Tokyo (JP)

(73) Assignee: Hitachi High-Technologies Corporation

(21) Appl. No.: 12/855,163

(22) Filed: Aug. 12, 2010

(30) Foreign Application Priority Data
Apr. 20, 2010 (JP) 2010-096869

(51) Int. Cl. H01L 21/465

(52) U.S. Cl. 156/345.46; 257/E21.485

(57) ABSTRACT

The present invention provides a plasma processing apparatus in which a plasma distribution, a plasma potential, an etching characteristic or a surface processing characteristic varies in time and spatially, and controllability and reliability are high. In the plasma processing apparatus, at least part of a discharge forming electromagnetic wave is introduced into a processing chamber through a transmission electrode. The transmission electrode is provided with a transmission electrode layer as at least part of constituent elements therefor. Slender-shaped slot opening areas are densely formed in the transmission electrode layer. The transmission electrode behaves like a material having electrical conductivity for an RF bias electromagnetic wave or ion plasma vibrations, thereby implementing high stability and high reliability of plasma characteristics and plasma processing characteristics.

### CLAIM OF PRIORITY

The present application claims priority from Japanese Patent Application 2010-096869 filed on Apr. 20, 2010, the content of which is hereby incorporated by reference into this application.

### BACKGROUND OF THE INVENTION

The present invention relates to a plasma processing apparatus using a transmission electrode, and particularly to a plasma processing apparatus suitable for processing a large diameter sample with a high degree of precision and uniformly. More particularly, the present invention relates to a magnetic type plasma processing apparatus having the above characteristics. Incidentally, a plasma etching apparatus or a plasma surface processing apparatus is generically called a plasma processing apparatus in the present specification. A sample is also called a wafer or a sample wafer, or a wafer sample.

A plasma etching apparatus has been used to form micro patterns on the surface of a sample (normally, a semiconductor wafer or a silicon wafer) in manufacturing semiconductor devices. The plasma etching apparatus is normally used to transfer a mask pattern formed in advance on the surface of the sample as a rugged pattern for the sample surface. A plasma surface processing apparatus has been used to carry out some kind of chemical and physical processing on the surface of the sample upon the manufacture of the semiconductor device. As the chemical and physical processing, there are mentioned a shape machining process like the plasma etching, a deposition process like CVD (Chemical Vapor Deposition), a modification process like surface oxidation or surface nitrization, or a cleaning process like ashing or removal of foreign materials, etc. The present invention will be explained below with the plasma etching apparatus as the principal prior art. The contents of the present invention can, however, be widely applied to the entire plasma surface processing apparatus. This is because the contents of the present invention relates to the plasma forming technology per se and can widely be applied to the entire plasma surface processing apparatus without any limitation to the contents of surface processing. In the present specification as described above, the plasma etching apparatus or the plasma surface processing apparatus is generically called plasma processing apparatus.

Although the present invention will be explained below assuming a magnetic type plasma etching apparatus (plasma processing apparatus) as a principal prior art, a part of the technology of the present invention can widely be applied to the entire plasma processing apparatus which does not necessarily have magnetic field forming means. This is because the present invention aims to solve problems exposed due to an increase in the diameter of a sample and realize a plasma processing apparatus having a high level of characteristics.

A form of a conventional representative plasma processing apparatus will be explained below.

FIG. 22 shows one example of a conventional plasma etching apparatus. A plasma etching apparatus 200 using a magnetic type microwave plasma is shown in the present drawing. A processing chamber 201 is provided and the inside of the processing chamber 201 is exhausted to vacuum. An etching gas (also called processing gas) is introduced into the processing chamber 201. Part of the etching gas and gas produced by the etching reaction are exhausted. The pressure of the introduced gas normally ranges from about 10⁻² Pa to about 100 Pa. This gas pressure range is, however, not necessarily strict. When it is desired to increase a processing speed and it is used for the deposition processing or the like, there is also a case in which the pressure is increased to 1 kPa and further to the atmospheric pressure (101 kPa). A discharge forming electromagnetic wave 202 is introduced into the processing chamber 201 through a discharge forming electromagnetic wave introduction window 203. The discharge forming electromagnetic wave introduction window 203 is normally comprised of a dielectric (electrical insulator) like quartz. In the apparatus shown in FIG. 22, the discharge forming electromagnetic wave 202 is supplied by a circular waveguide 204. A magnetic field is formed inside the processing chamber 201 by a cylindrical coil 205 (also called a solenoid coil).

With the interaction between this magnetic field and the discharge forming electromagnetic wave 202, and the etching gas, a discharge (also called plasma) is generated in at least partial area in the processing chamber 201. This discharge is a magnetic type microwave discharge (also called magnetic type microwave plasma). An area in which the discharge is generated is called a discharge area subsequently.

A sample table (also called sample holding means) 206 is laid inside the processing chamber 201. A sample (subsequently also called a wafer or a sample wafer, or a wafer sample) 207 is placed on the sample table 206. The sample table 206 and the sample 207 are connected to each other on an electric circuit basis. At least part of component parts of the sample table 206 is formed of an electrical conductor (also called an electrical conduction body or conductor). The sample table 206 is connected to a high frequency power supply 208 on an electric circuit basis.

The term “connected on the electric circuit basis” in the present specification does not necessarily means only the connection by the electrical conductor and also means the connection via an electric circuit part such as a capacitor, inductance, resistance or a switch. At this time, the function or facility to allow the value of the capacitance, inductance, resistance or the like (i.e., impedance) being the electric circuit part to vary may be provided. Further, the term “connected on the electric circuit basis” also means that materials (i.e., electrical conductors or electrical semiconductors) each having electrical conductivity are physically connected to each other (brought into contact with each other). Furthermore, the term “connected on the electric circuit basis” also means that materials (i.e., electrical conductors or electrical semiconductors) each having electrical conductivity are physically connected to each other through a thin film comprised of a dielectric (electrical insulator) material. This is because a high frequency current (e.g., RF current to be described below) enables conduction between the materials having electrical conductivity by capacitive coupling through the thin film of the dielectric material.

In the apparatus of FIG. 22, for example, the sample table 206 is connected to the high frequency power supply 208 via a capacitor 209, and a high frequency voltage (also called an RF voltage) is applied to the sample table 206. Thus, a bias voltage (subsequently called a high frequency bias voltage or an RF bias voltage) having a dc component is automatically applied to the sample table 206 and the sample 207. At least part of a wall that surrounds the processing chamber is connected to a ground potential (also called an earth potential) on an electric circuit basis. This wall is referred to as a ground potential wall. As a result, a high frequency current (RF current) is produced between the surface of the sample 207 and the ground potential wall via a discharge. With the above RF bias voltage, ions in the discharge (plasma) are accelerated and launched to the surface of the sample. Consequently, the physical and chemical surface reactions for etching are accelerated. The ground potential wall may be in direct contact with the discharge via the surface of a metal (electrical conductor substance). Alternatively, the ground potential wall may be in indirect contact with the discharge while the metal surface is being covered with a dielectric (electrical insulator) material having a predetermined thickness. This is because the high frequency current (RF current) with the high frequency voltage (RF voltage) is transferred via the dielectric (electrical insulator) material having the predetermined thickness to the metal surface of the ground potential wall through the discharge. The thickness of the dielectric (electrical insulator) material that covers the metal surface normally ranges from about 1 mm to about 10 mm. Covering the metal surface of the ground potential wall with the dielectric material as described above makes it possible to prevent the discharge (and therefore sample surface) from being contaminated with the metal material.

Electrons and ions are being produced during the discharge, and further reactive radicals are being produced by dissociation of an etching gas. Although electrically neutral, the reactive radicals are of atoms or molecules rich in chemical reactivity. As the etching gas, there are normally used gases containing freon such as CF₄, C₂F₆, C₃F₈, SF₆, Cl₂, BCl₃, etc., and a gas containing these gases as constituent elements. As a result, CF₃, CF₂, CF, F, Cl, BCl₂, BCl, etc. are produced as the reactive radicals. The ions produced during the discharge are those in which the molecules in the etching gas or the reactive radicals are positively or negatively charged.

A mask pattern is formed on the surface of the sample 207 in advance. The electrons and ions produced during the discharge, and the reactive radicals reach the surface of the sample 207 through each opening of the mask pattern. Further, the ions are accelerated by the above RF bias voltage and launched to the sample surface. As a result, the element that forms the sample and the element of the incident ion or incident reactive radical react with each other on the sample surface. This is referred to as an etching reaction. With the etching reaction, an evaporative (high vapor pressure) reactive product is produced. The reactive product is evaporated from the sample surface to the processing chamber as a generated gas. This generated gas is exhausted outside the processing chamber. According to such a process, the mask pattern is transferred as a rugged pattern of the sample surface. This corresponds to the process of plasma etching.

Next, FIG. 23 shows another example of a conventional plasma etching apparatus. A facing electrode plasma etching apparatus 200 is shown in the present drawing. A processing chamber 201 is provided and the inside of the processing chamber 201 is exhausted to vacuum. An etching gas is introduced into the processing chamber 201. Part of the etching gas and gas produced by the etching reaction are exhausted. A discharge forming electromagnetic wave 202 is introduced into the processing chamber 201 through a discharge forming electromagnetic wave introduction window 203. The discharge forming electromagnetic wave introduction window 203 is normally comprised of a dielectric (electrical insulator) like quartz. In the apparatus shown in FIG. 23, the discharge forming electromagnetic wave 202 is supplied by a coaxial waveguide 210. A central conductor 211 of the coaxial waveguide exists inside the coaxial waveguide 210. A magnetic field is formed inside the processing chamber 201 by a cylindrical coil 205 (also called a solenoid coil) as needed. This formation of magnetic field is, however, not an inevitable necessity.

A facing electrode 212 is laid with being connected to the central conductor 211 of the coaxial waveguide on an electric circuit basis. A wall corresponding to a wall surrounding the processing chamber 201 and near the facing electrode (called a near-facing electrode wall) 212 is formed of an electrical conductor and is normally placed in a ground potential. A discharge forming electromagnetic wave introduction window 203 is also laid even in a clearance space (referred to as a facing electrode upper portion clearance space) defined between the facing electrode 212 and a wall near the upper portion of the facing electrode 212. The discharge forming electromagnetic wave introduction window 203 may be configured with being divided into (a) an area near a connection part between the coaxial waveguide 210 and the processing chamber 201 and (b) a facing electrode upper portion clearance space area. The near-facing electrode wall may be in direct contact with the discharge via the surface of a metal (electrical conductor substance). Alternatively, the near-facing electrode wall may be in indirect contact with the discharge while the metal surface is being covered with a dielectric (electrical insulator) material having a predetermined thickness. The reason for this is similar to the contents explained in the description of the example of the prior art apparatus shown in FIG. 22.

A sample table (also called sample holding means) 206 is laid inside the processing chamber 201. A sample 207 is placed on the sample table 206. The sample table 206 and the sample 207 are connected to each other on an electric circuit basis. At least part of component parts of the sample table 206 is formed of an electrical conductor.

The facing electrode 212 and the sample table 206 are disposed opposite to each other. A space defined in such a way as to be sandwiched between the facing electrode 212 and the sample table 206 opposite to each other is referred to as an electrode-to-electrode space. The discharge forming electromagnetic wave 202 supplied by the coaxial waveguide 210 propagates from the inside (the central conductor 211 side of the coaxial waveguide) to the outside (the end edge portion side of the facing electrode 212) and is emitted from the end of the discharge forming electromagnetic wave introduction window 203 to the inside of the processing chamber 201. Next, the emitted discharge forming electromagnetic wave 202 propagates through the electrode-to-electrode space form the outside to the inside.

With the interaction between the discharge forming electromagnetic wave 202 propagating through the inside of the processing chamber 201 in this way and the etching gas, a discharge (also called plasma) is generated in at least partial area in the processing chamber 201. In particular, the electromagnetic field in the electrode-to-electrode space becomes strong so that the discharge is produced in the electrode-to-electrode space on a preferential basis.

The sample table 206 and the sample 207 are connected to each other on an electric circuit basis. At least part of component parts of the sample table 206 is formed of an electrical conductor. The sample table 206 is connected to a high frequency power supply 208 on an electric circuit basis. For example, the sample table 206 is connected to the high frequency power supply 208 via a capacitor 209, and hence a high frequency voltage (also called an RF voltage) is applied to the sample table 206. Thus, a bias voltage (subsequently called a high frequency bias voltage or an RF bias voltage) having a do component is automatically applied to the sample table 206 and the sample 207. At least part of the facing electrode 212 is connected to a ground potential (also called an earth potential) on an electric circuit basis. As a result, an RF current is generated between the surface of the sample 207 and the facing electrode 212 via the discharge. With the above RF bias voltage, ions in the discharge (plasma) are accelerated and launched to the surface of the sample. Consequently, the physical and chemical surface reactions for etching are accelerated.

A situation in which the etching process proceeds according to the above discharge (also called plasma), etching gas, RF bias voltage and RF current is similar to the situation explained in the description of the prior art shown in FIG. 22.

Japanese Unexamined Patent Publication No. Hei 6 (1994)-104098 (Hereafter, JP Hei 6-104098 A) has described a non-magnetic type microwave plasma processing apparatus wherein a microwave is oscillated by a microwave oscillator and introduced to a dielectric wave guide via a waveguide, and an electric field formed therebelow penetrates through a microwave introduction window and each transmission hole of earthed electrode means close to the microwave introduction window, thereby generating a plasma within a reaction chamber. As an example of the transmission hole, a slit shape has been disclosed.

The example of the conventional representative plasma etching apparatus has been shown above.

Incidentally, a TE₁₁ mode of a circular waveguide has been described in “Microwave Engineering—Fundamentals and Principles” by Masamitsu Nakajima (Morikita Publishing Co., Ltd.), Tokyo, 1975, pages 66-67.

### SUMMARY OF THE INVENTION

Generally, a higher density (higher electron density) discharge (plasma) can be formed as the frequency f_{pf} becomes higher. In the apparatus shown in FIG. 22, the frequency f_{pf} of the discharge forming electromagnetic wave 202 is normally used in a range of 0.1 GHz to 10 GHz. Of the frequency range, 0.5 GHz to 5 GHz is generally used and 2.45 GHz is used generally in particular. This is because the cutoff frequency of the electromagnetic wave propagating through the plasma is proportional to the square of an electron density ηe, and the discharge forming electromagnetic wave propagates and proceeds into a plasma having a higher electron density if the frequency f_{pf} of the discharge forming electromagnetic wave becomes larger, thereby to form and maintain the plasma. In this sense, it is general that the frequency f_{pf} (0.1 GHz to 10 GHz) having a higher value as compared with the apparatus shown in FIG. 23 later and other apparatuses is used in the apparatus shown in FIG. 22. When, however, the frequency f_{pf} becomes too high, the cost of discharge forming electromagnetic wave generating means becomes high. The cost of an electron cyclotron resonant magnetic field forming means becomes also high. The upper limit of the frequency f_{pf} is determined by these.

A magnetic flux density B₀ of a magnetic field formed inside the processing chamber 201, particularly, in the discharge region by the cylindrical coil 205 is normally used in a range of 0.01 T to 0.2 T. The number of effects obtained upon forming the magnetic field in the discharge area is at least two. One is to confine a plasma by the magnetic field and another is to efficiently form the plasma using electron cyclotron resonance. Both are effective at stably forming a higher density plasma (larger in electron density). Namely, they are effective at efficiently introducing the discharge forming electromagnetic wave in the discharge area. The effect of confining the plasma is effective for the magnetic field of the magnetic flux density B₀ of approximately 0.01 T or more. When the magnetic flux density B₀ of the magnetic field becomes too large, a facility for the magnetic field forming means (the cylindrical coil 205 in the apparatus of FIG. 22) and its running cost become large. This thus determines the upper limit of the magnetic flux density B₀ of the magnetic field. This upper limit is normally about 0.2 T.

When the plasma is formed using the electron cyclotron resonance, the magnetic field of the magnetic flux density B₀ determined by the following equation (1) is formed in at least partial area lying inside the processing chamber 201:

B₀=2πf_{pf}mₑ/qₑ (1)

where
π: ratio of circumference of circle to its diameter, π [symbol] 3.14159,
f_{pf}: frequency of the discharge forming electromagnetic wave [Hz]=[1/s],
mₑ: rest mass of electron [kg], mₑ [symbol] 9.109×10⁻³¹ kg, and
qₑ: quantum of electricity [C], qₑ [symbol] 1.602×10⁻¹⁹ C

In the present specification, the equation and physical quantities are expressed using the international system of units, i.e., SI (SI system of units). When the electron cyclotron resonance is used, a high density plasma (e.g. electron density ηe: ηe=1×10¹⁷ m⁻³ to 1×10¹⁸ m⁻³) can be formed at a wide range of gas pressure (e.g., 0.01 Pa to 1000 Pa). When f_{pf}=5 GHz, for example, B₀=0.179 T. When f_{pf}=2.45 GHz, B₀=0.0875 T. Further, when f_{pf}=1 GHz, B₀ =0.0357 T, whereas when f_{pf}=0.5 GHz, B₀=0.0179 T.

A frequency f_{rb} of an electromagnetic wave (RF bias electromagnetic wave) generated by a high frequency power supply is normally used in a range of 0.01 MHz to 100 MHz. In particular, a frequency f_{rb} ranging from 0.1 MHz to a few 10 MHz, and further a frequency f_{rb} ranging from 1 MHz to a few 10 MHz are more commonly used. This is because ion acceleration by the RF bias is performed more effectively and stably at this frequency.

Next, in the conventional apparatus shown in FIG. 23, the frequency f_{pf} of the discharge forming electromagnetic wave 202 is normally used in a range of 10 MHz to 1 GHz. While a high density plasma is easy to form as the frequency f_{pf} becomes extremely large, complex standing waves are easy to occur within the electrode-to-electrode space, so that the uniformity of the plasma is degraded. Practically, the actual frequency f_{pf} of discharge forming electromagnetic wave is determined while considering the plasma density (electron density) and the uniformity.

A situation in which the frequency f_{rb} of the electromagnetic wave (RF bias electromagnetic wave) generated by the high frequency power supply is selected is similar to the situation mentioned in the description of the prior art of FIG. 22.

In the apparatus of FIG. 23, means for introducing the etching gas is connected to the facing electrode 212 with tubing. The etching gas is supplied to the inside of the processing chamber 201 through a gas inlet (single or plural) formed in the surface on the electrode-to-electrode space side, of the facing electrode 212.

In the apparatus of FIG. 23 as described above, the facing electrode 212 is connected to its corresponding ground potential (also called earth potential) on the electric circuit basis. There is however a case in which in a similar apparatus, the facing electrode 212 is connected to its corresponding high frequency power supply on the electric circuit basis. In this case, the high frequency power supply (first high frequency power supply) to which the sample table 206 is connected on the electric circuit basis, and the high frequency power supply (second high frequency power supply) to which the facing electrode 212 is connected on the electric circuit basis, may be the same power supply, but may not be the same power supply.

The problems to be solved by the present invention are particularly manifested with an increase in the diameter (large boring) of the sample (wafer) subjected to etching or surface processing. Here, the sample diameter (or the diameter of sample) corresponds to the diameter when the sample is assumed to be approximately circular. According to the experiences, when the sample diameter reaches approximately 200 mm or more, the problem is manifested. If another expression is taken, the problem is more manifested when the sample diameter reaches approximately 250 mm or more, particularly, approximately 400 mm or more.

Problems to be described below are particularly manifested with the increase in the sample diameter when one attempts to realize plasma etching and surface processing with more advanced characteristics.

Namely, the problems which are manifested due to the increase in the diameter of the sample and are to be solved by the present invention are as follows:

(A) temporal and spatial variations in plasma potential,

(B) degradation in the uniformity of a plasma distribution,

(C) difficulty in ensuring the required area of RF-current ground potential electrode, and

(D) variations in physical and chemical surface states of the discharge side surface of the discharge forming electromagnetic wave introduction window.

They will concretely be explained below.

The problems (the above problems of (A), (B), (C) and (D)) related with respect to the prior art apparatus having the configuration of FIG. 22 will first be explained. In the prior art apparatus of FIG. 22, the discharge forming electromagnetic wave introduction window 203 is configured of the dielectric (electrical insulator). This becomes the cause of the occurrence of the problems.

A plasma potential varies in time and spatially due to ion plasma variations in a plasma. At the normal plasma density (plasma density ηₚ is considered to be equal to the electron density ηₑ: ηₚ=ηₑ=1×10¹⁶m⁻³ to 1×10¹⁸m⁻³), the frequency (number of vibrations) fₚᵢ of the ion plasma vibrations ranges approximately from fₚᵢ=2 MHz to 20 MHz. In the apparatus of FIG. 22, the discharge forming electromagnetic wave introduction window 203 is formed of the dielectric (electrical insulator) material. There is no electrical conductive material (electrical conductor or electrical semiconductor) for uniformizing or stabilizing the plasma potential in the neighborhood of the discharge forming electromagnetic wave introduction window 203. As a result, the problem associated with the temporal and spatial variations in the plasma potential with the increase in the diameter of the sample, accordingly, the increase in the diameter of the discharge forming electromagnetic wave introduction window 203 is manifested (problem (A1)). When a high frequency voltage (RF voltage) is applied to the sample table 206 (accordingly, the sample 207), RF current is generated through the discharge (plasma) between the surface of the sample 207 and the ground potential wall (the side wall of the processing chamber 201) as shown in FIG. 22. The length of a path for the RF current varies depending on the central portion of the sample surface and the end edge portion of the sample surface. Even by this, the problem associated with the temporal and spatial variations in the plasma potential is manifested (problem (A2)).

As described above, when the high frequency voltage (RF voltage) is applied to the sample table 206 (accordingly, sample 207), the RF current is generated via the discharge (plasma) between the surface of the sample 207 and the ground potential wall. If, at this time, the area of the ground potential wall is sufficiently larger than the area of the surface of the sample 207, most of the RF bias voltage corresponding to the dc component is applied between the sample surface and the plasma potential, so that ions in the plasma are effectively accelerated to the sample surface. At this time, the plasma potential relative to the ground potential becomes approximately constant. Namely, the condition of the following equation (2) is required to bring out the effect of the RF bias sufficiently:

S_{sb}<<S_{gw} (2)

where,
S_{sb}: area of the surface of the sample 207 [m²] and area of the sample surface brought into contact with the plasma, and
S_{gw}: area of the ground potential wall [m²].

When the diameter of the sample is however increased, the relationship of the above equation (2) is not necessarily established. This is because when the sample diameter is assumed to be D_{sb}, S_{sb} increases in proportion to approximately D_{sb}², and S_{gw} increases in proportion to approximately D_{sb}. Namely, it becomes difficult to ensure the required area of RF current ground potential electrode with the increase in the sample diameter (problem (C)).

In the apparatus of FIG. 22, the discharge forming electromagnetic wave introduction window 203 is comprised of the dielectric (electrical insulator) material. As a result, the surface on the discharge side, of the discharge forming electromagnetic wave introduction window (hereinafter called an introduction window surface) is placed in a potential lowered by a floating voltage with respect to the adjacent plasma potential. The amounts of flow of positive and negative charges (normally, ions and electrons) from the plasma to the introduction window surface become equal. The floating voltage is normally about 20 V. The effect of allowing ions accelerated by this voltage to sputter or clean the introduction window surface is small. Namely, reactive product molecules for the sample etching are attached to and deposited on part of the introduction window surface. As a result, the physical and chemical surface states of the introduction window surface vary. Further, this variation increases with the increase in the diameter of the discharge forming electromagnetic wave introduction widow 203 due to the reason mentioned in the section of (A) (problem (D)).

The problem (the above problem of (B)) related with respect to the prior art apparatus having the configuration of FIG. 23 will next be explained. In the prior art apparatus of FIG. 23 as described above, the discharge forming electromagnetic wave 202 propagates in the following manner. Namely, the discharge forming electromagnetic wave 202 supplied by the coaxial waveguide 210 propagates through the facing electrode upper portion clearance space from the inside (the central conductor 211 side of the coaxial waveguide) to the outside (the end edge portion side of the facing electrode 212) and is emitted from the end of the discharge forming electromagnetic wave introduction window 203 to the inside of the processing chamber 201. Next, the emitted discharge forming electromagnetic wave 202 propagates through the electrode-to-electrode space from the outside to the inside. The discharge forming electromagnetic wave 202 injects power into the corresponding plasma in process of propagating through the electrode-to-electrode space from the outside to the inside and is gradually reduced itself in intensity. Part thereof is reflected by the central part of the electrode-to-electrode space and forms a standing wave (stationary wave) within the electrode-to-electrode space. As a result, a distribution of the characteristics (such as an electron density, an electron temperature, etc.) of the formed plasma becomes ununiform. This is manifested with the diameter of the sample table or the diameter of the sample (problem (B)).

In the prior art apparatus of JP Hei 6-104098 A, the earthed electrode means having the transmission holes (slits) is placed in contact with the microwave introduction window. Therefore, the facing electrode relative to the sample holding portion is found to be distinct and hence a bias voltage stable for the sample surface can be generated. Thus, JP Hei 6-104098 A has described that there are effects such as an ability to stabilize the plasma potential produced within the reactive chamber by the microwave having penetrated through each slit, etc. JP Hei 6-104098 A does not, however, discuss or examine the importance placed on a distribution of the slits (corresponding to the slot opening areas of the subject invention) in a “dense” form. Accordingly, structural numerical values for fixing the shapes of the transmission slits and their distribution are not completely explained. The apparatus of JP Hei 6-104098 A corresponds to the non-magnetic type microwave plasma processing apparatus and does not involve the problem associated with the cross impedance or the voltage drop (change in potential) due to the cross impedance, peculiar to the magnetic type plasma processing apparatus. No consideration is therefore given to the above problem as to the configuration of the slit.

An object of the present invention is to solve the problems manifested due to the increase in the diameter of the sample, i.e., the following problems of (A) through (D) and thereby realize a plasma etching apparatus and a surface processing apparatus both having more advanced characteristics, i.e., a plasma processing apparatus. The present invention is particularly directed to the realization of a magnetic type plasma processing apparatus having the above characteristics.

(A) temporal and spatial variations in plasma potential,

(B) degradation in the uniformity of a plasma distribution,

(C) difficulty in ensuring the required area of RF-current ground potential electrode, and

(D) variations in physical and chemical surface states of the discharge side surface of the discharge forming electromagnetic wave introduction window.

The present invention has been made to solve the above problems by the adoption of a transmission electrode.

There is provided a plasma processing apparatus for performing plasma processing, having a representative configuration of the present invention including a processing chamber, means for introducing a processing gas into the processing chamber, means for producing a discharge in at least partial areas in the processing chamber, means for forming a magnetic field in at least part of the discharge-produced discharge area and means for holding a sample to be processed,

wherein each of the discharge-produced areas is provided as a discharge area,

wherein the plasma processing apparatus has magnetic field forming element for forming a magnetic field in at least partial area of the discharge areas,

wherein the plasma processing apparatus has element for introducing a discharge forming electromagnetic wave into the processing chamber, as at least part of the discharge producing means,

wherein the plasma processing apparatus has a transmission electrode for introducing at least part of the discharge forming electromagnetic wave into the corresponding discharge area,

wherein the plasma processing apparatus has a transmission electrode layer as at least part of constituent elements of the transmission electrode,

wherein the transmission electrode layer includes an electrical conductor or an electrical semiconductor corresponding to a material having electrical conductivity,

wherein the transmission electrode layer has an electromagnetic wave transmission area,

wherein a plurality of slot opening areas comprised of transmission electrode layer lacking areas each having a slender shape are formed in the electromagnetic wave transmission area,

wherein each of the slot opening areas is of an area in which the material having the electrical conductivity, forming the transmission electrode layer, is lacked in the transmission electrode layer,

wherein, when a direction parallel to a long side of the slot opening area is assumed to be a longitudinal direction, a direction perpendicular to the longitudinal direction thereof is assumed to be a transverse direction, a length of the slot opening area extending along the longitudinal direction thereof is assumed to be a slot opening length Lₛₛ, a length thereof extending along the transverse direction is assumed to be a slot opening width Wₛₛ, and Aₛ=Lₛₛ/Wₛₛ is assumed to be an aspect ratio of the slot opening area, the slot opening area whose slot opening width Wₛₛ ranges from 0.01 mm to 10 mm and whose aspect ratio Aₛ is 10 or more exists as more than at least one,

wherein, when an axis which corresponds to an axis approximately parallel to the longitudinal direction of each of the slot opening areas and which divides each slot opening area approximately equally, is assumed to be a transverse central axis, a pair of the slot opening areas between which a slot period width Wₛₚ becomes 10 mm or less exist as more than at least one, assuming a distance between transverse central axes adjacent to each other as the slot period width Wₛₚ, and

wherein when the area of the electromagnetic wave transmission area is assumed to be Sₜₜ, the sum of the areas of the slot opening areas existing within the electromagnetic wave transmission area is assumed to be S_{SS}, and Rₛₜ=Sₛₛ/Sₜₜ is assumed to be a slot opening ratio, the slot opening ratio Rₛₜ is 0.01 or more.

According to another aspect of the plasma processing apparatus of the present invention, wherein when h_{d} is assumed to be a mean value of discharge area heights, a is assumed to be an allowable aspect ratio, dₛ is assumed to be a diameter or equivalent diameter of the sample, Δh_{d} is assumed to be a value of a variation in the discharge area height, and b is assumed to be an allowable variation ratio, h_{d} and Δh_{d} satisfy relationships expressed in the following equations (A3-1) and (A3-2):

h_{d}≦adₛ (A3-1)

Δh_{d}≦bh_{d} (A3-2).

According to the present invention, a discharge forming electromagnetic wave can be introduced into a processing chamber through a transmission electrode. It is thus possible to suppress temporal and spatial variations in plasma distribution, plasma potential, etching characteristics or surface processing characteristics. Consequently, a plasma processing apparatus can be realized which is high in controllability and reliability. A plasma processing apparatus can particularly be provided which processes a large diameter sample highly uniformly. Further, a magnetic type plasma processing apparatus having the above characteristics can particularly be provided.

### BRIEF DESCRIPTION OF THE DRAWINGS

FIG. 1 is a diagram showing a vertical section of a plasma processing apparatus according to a first embodiment of the present invention;

FIG. 2A is a diagram illustrating a basic configuration of a transmission electrode of the present invention and a state of its use;

FIG. 2B is a diagram illustrating a basic configuration of a transmission electrode of the present invention and another state of its use;

FIG. 3 is a plan view showing a structural example of a slot opening area at a transmission electrode layer;

FIG. 4 is a diagram showing an electric field at the slot opening area;

FIG. 5 is a partly enlarged view of an electromagnetic wave transmission area shown in FIG. 3;

FIG. 6 is a diagram typically illustrating the process of allowing a discharge forming electromagnetic wave to pass through a transmission electrode layer to thereby absorb the same into discharge areas;

FIG. 7 is a diagram typically showing the process of absorbing a discharge forming electromagnetic wave under a condition other than that shown in FIG. 6 as a comparative example;

FIG. 8 is a diagram depicting a voltage drop at the transmission electrode layer due to RF current and a voltage induced in an electrode protection layer in the present invention;

FIG. 9 is a diagram illustrating a vertical section of a plasma processing apparatus according to a second embodiment of the present invention;

FIG. 10 is a plan view showing a structural example of a slot opening area in a transmission electrode layer according to a third embodiment;

FIG. 11 is a partly enlarged view of an electromagnetic wave transmission area in FIG. 10;

FIG. 12 is a plan view showing a structural example of a slot opening area in a transmission electrode layer according to a fourth embodiment;

FIG. 13 is a partly enlarged view of an electromagnetic wave transmission area shown in FIG. 12;

FIG. 14A is a partly enlarged view of an electromagnetic wave transmission area at a transmission electrode layer according to a fifth embodiment;

FIG. 14B is a partly enlarged view of another example of an electromagnetic wave transmission area at the transmission electrode layer according to the fifth embodiment;

FIG. 15A is a diagram typically showing an electric field (lines of electric force) and a magnetic field (lines of magnetic force) in a TE₁₁ mode of a circular waveguide at the position of the transmission electrode;

FIG. 15B is a diagram depicting an example illustrative of shapes and arrangements of slot opening areas for allowing a discharge forming electromagnetic wave in the circular waveguide TE₁₁ mode at the position of the transmission electrode to pass therethrough efficiently and uniformly;

FIG. 15C is a diagram showing an example illustrative of other shapes and arrangements of slot opening areas for allowing the discharge forming electromagnetic wave in the circular waveguide TE₁₁ mode at the position of the transmission electrode to pass therethrough efficiently and uniformly;

FIG. 16 is a sectional view illustrating a transmission electrode according to a sixth embodiment of the present invention and part of its neighborhood;

FIG. 17 is a sectional view of a transmission electrode according to a seventh embodiment of the present invention;

FIG. 18 is a sectional view showing a transmission electrode according to an eighth embodiment of the present invention and part of its neighborhood;

FIG. 19 is a sectional view illustrating a transmission electrode according to a ninth embodiment of the present invention and part of its neighborhood;

FIG. 20A is a sectional view illustrating a transmission electrode according to a tenth embodiment of the present invention and part of its neighborhood;

FIG. 20B is a diagram typically showing a state of laying of transmission electrode cooling means having the function of cooling the transmission electrode by the flow of a cooling gas, according to the tenth embodiment of the present invention;

FIG. 21A is a top schematic diagram of a plasma processing apparatus according to an eleventh embodiment of the present invention;

FIG. 21B is a side schematic diagram of the plasma processing apparatus according to the eleventh embodiment of the present invention;

FIG. 22 is a diagram showing a vertical section of a magnetic type microwave plasma etching apparatus according to a prior art; and

FIG. 23 is a diagram illustrating a vertical section of a facing electrode plasma etching apparatus according to a prior art.

### DETAILED DESCRIPTION OF THE PREFERRED EMBODIMENT

A summary of representative ones of the inventions disclosed in the present specification will be described as follows:

(1) There is provided a plasma processing apparatus including:

a processing chamber;

means for introducing a processing gas into the processing chamber;

means for producing a discharge in at least partial areas in the processing chamber; and

means for holding a sample,

wherein the processing chamber, the processing gas introducing means, the discharge producing means and the sample holding means are provided as at least parts of constituent elements,

wherein the sample is introduced into the processing chamber to perform plasma processing,

wherein each of the discharge-produced areas is referred to as a discharge area,

wherein the plasma processing apparatus has means for introducing a discharge forming electromagnetic wave into the processing chamber, as at least part of the discharge producing means,

wherein at least part of the discharge forming electromagnetic wave is introduced into the corresponding discharge area through a transmission electrode,

wherein the plasma processing apparatus has a transmission electrode layer as at least part of constituent elements of the transmission electrode,

wherein the transmission electrode layer includes an electrical conductor or an electrical semiconductor corresponding to a material having electrical conductivity, and

wherein the transmission electrode layer is comprised of a transmission electrode in which slender-shaped slot opening areas are densely formed.

Namely, the transmission electrode layer has an electromagnetic wave transmission area, wherein plural transmission electrode layer lacking areas each having a slender shape are formed in the electromagnetic wave transmission area, wherein each of the transmission electrode layer lacking areas is of an area in which a material having electrical conductivity, forming a transmission electrode layer is lacked in the transmission electrode layer.

When the transmission electrode layer lacking area having the slender shape is referred to as a slot opening area, the direction parallel to the long side of the slot opening area is referred to as a longitudinal direction, the direction perpendicular to the longitudinal direction thereof is referred to as a transverse direction, the length of the slot opening area extending along the longitudinal direction thereof is referred to as a slot opening length Lₛₛ, the length thereof extending along the transverse direction is referred to as a slot opening width Wₛₛ, and Aₛ=Lₛₛ/Wₛₛ is referred to as an aspect ratio of the slot opening area, the slot opening area whose aspect ratio Aₛ is 10 or more exists as more than at least one.

When an axis which corresponds to an axis approximately parallel to the longitudinal direction of each of the slot opening areas and which divides each slot opening area approximately equally, is assumed to be a transverse central axis, a pair of the slot opening areas between which a slot period width Wₛₚ becomes 10 mm or less exists as more than at least one, assuming a distance between the transverse central axes adjacent to each other as the slot period width Wₛₚ.

When the area of the electromagnetic wave transmission area is assumed to be Sₜₜ, the sum of the areas of the slot opening areas existing within the electromagnetic wave transmission area is assumed to be Sₛₛ, and Rₛₜ=Sₛₛ/Sₜₜ is assumed to be a slot opening ratio, the slot opening ratio Rₛₜ is 0.01 or more.

(2) There is provided a plasma processing apparatus wherein in the plasma processing apparatus described in the above (1), an electrical insulator or an electrical semiconductor is charged into at least part of the slot opening areas.

(3) There is provided a plasma processing apparatus wherein in the plasma processing apparatus described in the above (1) or (2), the sample held by the sample holding means and the transmission electrode or the transmission electrode layer are disposed opposite to each other, and h_{d} and Δh_{d} satisfy relationships expressed in the following equations (A3-1) and (A3-2):

h_{d}≦adₛ (A3-1)

Δh_{d}≦bh_{d} (A3-2)

where h_{d} indicates a mean value of discharge area heights, a indicates an allowable aspect ratio, dₛ indicates a diameter or equivalent diameter of the sample, Δh_{d} indicates a value of a variation in the discharge area height, and b indicates an allowable variation ratio respectively, and the allowable aspect ratio a=1, and the allowable variation ratio b=½.

(4) There is provided a plasma processing apparatus wherein in the plasma processing apparatus described in any of the above (1) through (3), means for forming a magnetic field in at least part of the discharge areas is provided.

(5) There is provided a plasma processing apparatus wherein in the plasma processing apparatus described in any of the above (1) through (4), the slot opening area whose slot opening width Wₛₛ ranges from 0.1 mm to 10 mm exists as more than at least one.

(6) There is provided a plasma processing apparatus wherein in the plasma processing apparatus described in any of the above (1) through (5), the slot opening length Lₛₛ satisfies a relationship expressed in the following equation (A6-1):

Lₛₛ≧A_{pf}_{_{—}}ₛλ_{pf}/2 (A6-1)

where λ_{pf} indicates a wavelength when the discharge forming electromagnetic wave propagates through vacuum, and

the slot opening area in which A_{pf}_{_{—}}ₛ=0.7 exists as more than at least one.

(7) There is provided a plasma processing apparatus wherein in the plasma processing apparatus described in any of the above (1) through (6), the transmission electrode is installed within a circular waveguide, and each of the slot opening areas is formed in such a manner that the locally-defined transverse direction of the slot opening area becomes parallel to the direction of an electric field in a TE₁₁ mode of the circular waveguide at the corresponding location.

(8) There is provided a plasma processing apparatus wherein in the plasma processing apparatus described in any of the above (1) through (7), the transmission electrode is installed within a circular waveguide, a coupled rectangular waveguide indirectly or directly coupled to the circular waveguide is provided, and the discharge forming electromagnetic wave sequentially propagates through the coupled rectangular waveguide and the circular waveguide and is launched into the transmission electrode, and

the transmission electrode is installed in such a manner that the transverse direction of each of the slot opening areas, or the mean transverse direction of the slot opening area in the transmission electrode layer, or the local transverse direction of the slot opening area in the vicinity of the center of the transmission electrode layer becomes parallel to the axial direction of the coupled rectangular waveguide.

(9) There is provided a plasma processing apparatus wherein in the plasma processing apparatus described in any of the above (1) through (8), an area other than the slot opening areas is called a non-slot opening area in the transmission electrode layer; a single or plural transmission electrode layer lacking areas are formed in at least part of the non-slot opening area; and the transmission electrode layer lacking area in the non-slot opening area is called a second opening area, which is of an area having an arbitrary shape, in which a material having electrical conductivity, forming the transmission electrode layer is lacked in the transmission electrode layer.

(10) There is provided a plasma processing apparatus wherein in the plasma processing apparatus described in the above (9), at least part of the processing gas is introduced into the processing chamber through the second opening area.

Preferred embodiments of the present invention will hereinafter be explained in detail with reference to the accompanying drawings. In all of the drawings for explaining the embodiments, portions having the same functions as those in the prior art are identified by like reference numerals, and their repetitive description will be omitted.

### First Embodiment

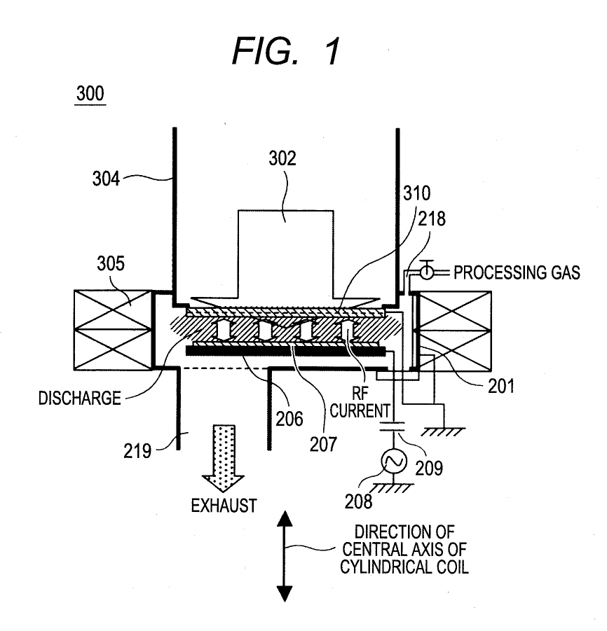

A plasma processing apparatus according to a first embodiment of the present invention will be explained with reference to FIG. 1 and FIGS. 2A through 8. A vertical section of the plasma processing apparatus 300 according to the first embodiment of the present invention is shown in FIG. 1. A discharge forming electromagnetic wave 302 is supplied to a circular waveguide 304. A transmission electrode 310 (or transmission electrode layer 312) is provided between the circular waveguide 304 and a processing chamber 201. The transmission electrode 310 and a sample placement surface of a sample table 206 lying within the processing chamber 201 are disposed opposite to each other. This results in a structure of a facing electrode arrangement in which the transmission electrode 310 and a sample 207 are disposed opposite to each other. A cylindrical coil (solenoid coil) 305 corresponding to magnetic field forming means (element) is disposed around the processing chamber 201. The discharge forming electromagnetic wave 302 has a frequency f_{pf} ranging from 0.1 GHz to 10 GHz. An etching gas (processing gas) is introduced into the processing chamber 201 through a processing gas supply port 218, so that part of the etching gas lying in the processing chamber 201 and gas generated by the etching reaction are exhausted to the outside via an exhaust port 219.

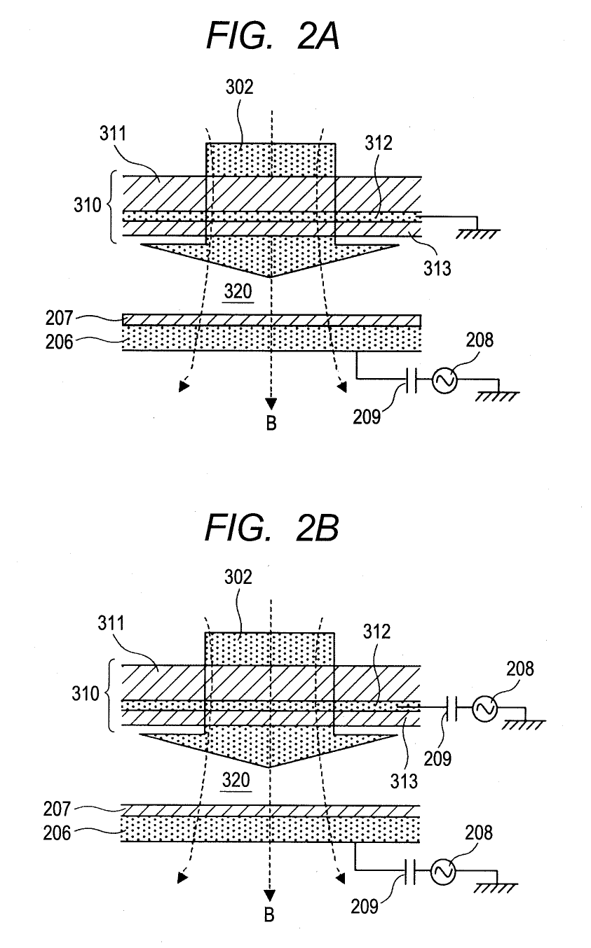

While the configuration and function of the transmission electrode 310 will be described in detail later in the section of “basic configuration of transmission electrode”, one example of its configuration is shown in FIG. 2A. The transmission electrode 310 has a flat structure in which a transmission electrode layer 312 and an electrode protection layer 313 are laminated over the surface of an electrode substrate 311. The electrode substrate 311 is formed by a dielectric or dielectric material (electrical insulator), and the electrode protection layer 313 is formed by either a dielectric material (electrical insulator) or a semiconductor or by a combination of these. The transmission electrode layer 312 is comprised of an electrical conductor or an electrical semiconductor which serves as a material having electrical conductivity. The transmission electrode layer has an electromagnetic wave transmission area in which plural transmission electrode layer lacking areas (slot opening areas) each having a slender shape are formed. In the present embodiment, the transmission electrode layer 312 of the transmission electrode 310 is connected to a ground potential on an electric circuit basis. The sample table 206 is connected to a high frequency power supply 208 via a capacitor 209 on an electric circuit basis. A high frequency voltage (RF voltage) is applied to the sample table 206. A magnetic field B having a substantially vertical direction vector is distributed substantially over the entire sample placement surface, i.e., the entire to-be-processed surface of the sample in the neighborhood of the sample 207. The direction of the vector of the magnetic field B is not necessarily required to be substantially vertical to the processed surface. More generally, it can be represented that the magnetic field B is incident on the processed surface substantially over the entire to-be-processed surface.

As the method of connecting the transmission electrode layer 312 to the ground potential on an electric circuit basis as in the example of FIG. 2A, there can be provided, for example, a method of directly connecting the surface of an end edge portion of a transmission electrode layer to a vacuum wall of a processing chamber, or a method of connecting the surface of an end edge portion of a transmission electrode layer to a vacuum wall of a processing chamber through a thin film (single or plural thin films) comprised of a dielectric (electrical insulator) material. In this case, the vacuum wall of the processing chamber is made up of a metal (electrical conductor) and is assumed to be connected to the ground potential in advance on an electric circuit basis. The vacuum wall of the processing chamber corresponds to the wall provided to hold the inside of the processing chamber (or discharge area) in a vacuum. The thin film of the dielectric (electrical insulator) material may cover the surface of the end edge portion of the transmission electrode layer or cover the surface of the vacuum wall of the processing chamber. Alternatively, the thin film may cover both thereof (in this case, the number of thin films becomes two or more). These thin films are referred to as thin films to be coated. Coating the surface of the end edge portion of the transmission electrode layer or the surface of the vacuum wall of the processing chamber with the thin film of the dielectric (electrical insulator) material in this way makes it possible to prevent these surfaces from being corroded dude to a reactive gaseous atmosphere. The coated thin film (called “end edge portion thin film to be coated”) of the surface of the end edge portion of the transmission electrode layer can be formed of the same material as the electrode protection layer 313 or the electrode substrate 311 to be described later. Doing so makes it easy to fabricate the transmission electrode 310. It is, however, necessary to normally make the thickness of the end edge portion thin film thinner than the thickness (thickness at electromagnetic wave transmission area 3121) of the electrode protection layer 313 or the electrode substrate 311. This is because it is necessary to allow RF current to pass through the end edge portion thin film sufficiently. Considering the corrosion resistance, physical strength and the conductive property of the RF current, the practical thickness of the end edge portion thin film ranges from 0.01 mm to 1 mm. The practical thickness of the coated thin film (called “vacuum wall thin film to be coated”) of the surface of the vacuum wall of the processing chamber also ranges from 0.01 mm to 1 mm.

According to the present embodiment, the discharge forming electromagnetic wave 302 (or part of discharge forming electromagnetic wave 302) is introduced into its corresponding discharge area 320 of the processing chamber 201 through the transmission electrode 310. The discharge forming electromagnetic wave 302 (or part of discharge forming electromagnetic wave) is supplied from the electrode substrate 311 side to the discharge area 320 through the corresponding slot opening area of the transmission electrode layer 312 and the electrode protection layer 313. Since the transmission electrode layer 312 is connected to the ground potential on the electric circuit basis, it is possible to cause the RF current to flow to the ground potential.

Incidentally, although not shown in FIG. 1, the transmission electrode layer 312 can also be set to a floating potential at a form equal to the present embodiment. As in a configuration example of FIG. 2B, the transmission electrode layer 312 may be connected to its corresponding high frequency power supply 208 on an electric circuit basis. The details of the configuration example of FIG. 2B will be explained later.

The desired ranges of the basic configuration of the transmission electrode applied to the first embodiment of the present invention shown in FIG. 1 and of structure numerical values of the shape of each slot opening area, the thickness of the transmission electrode layer, the thickness of the electrode protection layer, the thickness of the electrode substrate, etc. will be explained in detail later in the sections of “basic configuration of transmission electrode”, “slot opening area at transmission electrode layer and its structure”, “thickness of transmission electrode layer”, “thickness of electrode protection layer”, and “thickness of electrode substrate”. One example illustrative of structural materials and structure numerical values employed in the first embodiment of the present invention shown in FIG. 1 will concretely be explained herein. The frequency of the discharge forming electromagnetic wave is f_{pf}=2.45 GHz. The electrode substrate is formed of yttria (Y₂O₃) or quartz (SiO₂), and the thickness thereof is dₑₛ=25 mm. The electrode protection layer is formed of yttria (Y₂O₃) or quartz (SiO₂), and the thickness thereof is dₑₚ=1 mm. The transmission electrode layer is formed of titanium (Ti) or aluminum (Al), and the thickness thereof ranges from dₜₑ=0.1 mm to 0.3 mm. Each slender-shaped slot opening area is formed in the transmission electrode layer. Its structure numerical values are as follows: slot opening length Lₛₛ=65 mm, slot gap length L_{sg}=5 mm, slot period length Lₛₚ=70 mm, slot opening width Wₛₛ=0.5 mm, slot gap width W_{sg}=0.5 mm, and slot period width Wₛₚ=1 mm. Accordingly, a slot opening rate Rₛₜ is Rₛₜ [symbol] WₛₛLₛₛ/(WₛₚLₛₚ)=0.46.

Although the electrode substrate 311 and the electrode protection layer 313 have been shown in the configuration example of FIG. 2A, they are not necessarily required as components. The transmission electrode 310 can also be configured only by the transmission electrode layer 312. The functions to be held by the transmission electrode 310, i.e., the function of allowing the discharge forming electromagnetic wave to pass therethrough and the function of allowing the RF current to flow to the ground potential or external high frequency power supply can also be realized by the transmission electrode layer 312 alone.

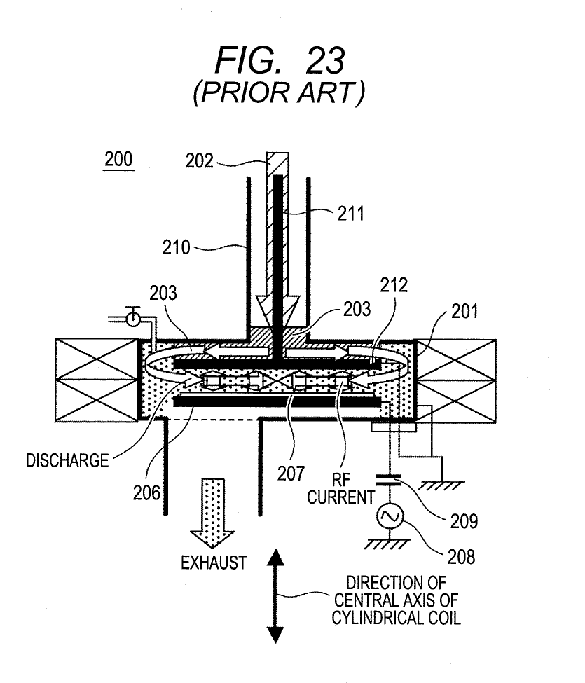

The frequency f_{pf} of the discharge forming electromagnetic wave 302 and the frequency f_{rb} of an RF bias electromagnetic wave both employed in the apparatus according to the present embodiment are equivalent to those described in the prior art apparatuses shown in FIGS. 22 and 23. In addition to the above, detailed explanations of those similarly applicable to the plasma processing apparatus of the present invention, such as the configurations of the sample table in the processing chamber 201 and the like, the etching gas therein, and physical and chemical reactions in surfaces for etching, discharge magnetic fields, etc., which have been described in relation to each of the apparatuses shown in FIGS. 22 and 23, will be omitted.

As described above, the transmission electrode 310 according to the present embodiment has the function of allowing the discharge forming electromagnetic wave to pass therethrough and the function of causing the RF current to flow to the ground potential or the external high frequency power supply. Namely, the transmission electrode 310 acts like the dielectric (electrical insulator) for the discharge forming electromagnetic wave (whose frequency f_{pf} normally ranges from 0.01 GHz to 10 GHz) and acts like a material having electrical conductivity for the RF bias electromagnetic wave (whose frequency f_{rb} normally ranges from 0.01 MHz to 100 MHz and f_{rb}<f_{pf}) or an electromagnetic wave (whose frequency fₚᵢ ranges approximately from fₚᵢ=2 MHz to 20 MHz) for ion plasma vibrations. Such seemingly contradictory functions can be realized simultaneously because they depend on each slot opening area formed in the transmission electrode and its structure as will be described in detail later in the section of “basic configuration of transmission electrode”.

Particularly when it is desirable to form high-density (high-electron density) discharge (plasma) in the present embodiment, it is desired that the frequency the discharge forming electromagnetic wave 302 is set to 0.1 GHz to 10 GHz. In the apparatus according to the present embodiment, the transmission electrode 310 also functions as a vacuum chamber wall and has a structure in which it can withstand differential pressure between the atmospheric pressure and pressure in the processing chamber. The transmission electrode 310, however, needs not to always double as the action of the vacuum chamber wall. A configuration in which the transmission electrode 310 is placed inside the processing chamber, is also enabled.

As shown in FIG. 1, in the present embodiment wherein the facing electrode arrangement is taken in which the transmission electrode 310 and the sample 207 are disposed opposite to each other, the RF current flows between the sample and the transmission electrode 310, substantially perpendicular to the processed surface over the entire range of the processed surface of the sample 207 and at an approximately constant length without its current path length being dependent on the location of the sample surface, unlike the prior art apparatus of FIG. 22. In other words, a distribution (ion's kinetic energy) of acceleration of ions incident on the sample surface is uniform within the processed surface of the sample 207. In the present embodiment, many of required areas for the RF-current ground potential electrode are ensured by the transmission electrode 310. It is therefore possible to reduce the area of the RF-current ground potential electrode to be ensured by the side wall of the processing chamber 201 and reduce the volume (diameter and height of processing chamber) of the processing chamber unlike the prior art apparatus of FIG. 22. Therefore, the cylindrical coil (solenoid coil) 305 corresponding to the magnetic field forming means can be disposed around the processing chamber 201 without making the entire shape of the plasma processing apparatus large and increasing the cost of the magnetic field forming means. It is thus possible to enhance the uniformity of a magnetic field distribution in the neighborhood of the sample.

Further, unlike the prior art apparatus of FIG. 23 in which the discharge forming electromagnetic wave is supplied by the coaxial waveguide, the occurrence of complex standing waves in an electrode-to-electrode space is also suppressed. Therefore, an electromagnetic wave strength distribution is uniform within the processed surface of the sample 207.

Therefore, in the plasma processing apparatus according to the present embodiment, an uniform plasma is generated over the whole in-plane range of the processed surface of the sample 207. There can thus be provided a plasma processing apparatus which processes a large diameter sample in a high uniform manner.

The structure of the transmission electrode 310 according to the present embodiment and its constituent materials will now be described. The transmission electrode 310 has, as one example, a structure or configuration in which the transmission electrode layer 312 and the electrode protection layer 313 are laid on the surface of the electrode substrate 311. As the way to lay them, laminating, or a physical or chemical lamination or the like is possible. The electrode substrate 311 is formed of dielectric, e.g., quartz, and the thickness thereof is 25 mm. The thickness of the electrode substrate 311 is designed to withstand the differential pressure between the atmospheric pressure and the pressure in the processing chamber. The constituent material of the electrode substrate 311 is not necessarily required to be quartz. It is needless to say that dielectrics (electrical insulators) of MgO (magnesium oxide), CaO (calcium oxide), Al₂O₃ (aluminum oxide, alumina), Y₂O₃ (yttrium oxide, yttria), MgF₂ (magnesium fluoride), CaF₂ (potassium fluoride), AlF₃ (aluminum fluoride), YF₃ (yttrium fluoride), etc. or a mixture of these can be used as the constituent material. Although the chemical formulas are used to represent the above compounds, this does not mean that the elementary composition ratios of these substances strictly coincide with the chemical formulae on a stoichiometric basis. It is a matter of course that the substances brought to approximately such composition ratios are widely contained for the constituent materials. This similarly applies to all aspects of the specification of the present application.

The transmission electrode layer 312 is formed of Al (aluminum), and the thickness thereof is 0.3 mm. Plural slender-shaped slot opening areas are formed in the transmission electrode layer 312. The constituent material of the transmission electrode layer 312 is not necessarily required to be Al. An electrical conductor or an electrical semiconductor can generally be used as the constituent material. As the electrical conductor, there can be used, for example, any of metals such as Ti (titanium), Cr (chromium), Ni (nickel), Fe (ferrum), Al (aluminum), Cu (copper), Ag (argentum), Au (aurum), etc., or an alloy containing at least some of these, or a material containing at least some of these. As the electrical semiconductor, there can be used, for example, Si, SiC, C or a compound semiconductor, or a material in which these are doped with an impurity.

The electrode protection layer 313 is formed of a dielectric, e.g., quartz, and the thickness thereof is 1 mm. The constituent material of the electrode protection layer 313 does not necessarily need to be formed of quartz. The dielectrics (electrical insulators) or the mixture of these described in the section of the constituent material of the electrode substrate 311, or the electrical semiconductor described in the section of the constituent material of the transmission electrode layer 312 can generally be used as the constituent material.

Incidentally, the concrete structure of the transmission electrode 310 and its concrete constituent material will be explained in detail later.

Solutions to the problems (A) (or (A1), (A2)), (B), (C) and (D) of the prior art apparatuses by the apparatus (apparatus shown in FIG. 1) according to the present embodiment will be described in detail later in the section of “basic configuration of transmission electrode”.

In the plasma processing apparatus of the facing electrode arrangement and the plasma processing apparatus having means for forming the magnetic field in the processing chamber or each discharge area, the present invention further brings about specific advantageous effects. The specific advantageous effects will be explained below using the apparatus according to the present embodiment of FIG. 1 and the prior art apparatus of FIG. 22.

In the apparatus according to the present embodiment and the prior art apparatus, the magnetic fields are formed inside the processing chambers 201 by the cylindrical coils 205 and 305 (also called “solenoid coils”). The cylindrical coils (also called “solenoid coils”) correspond to the “magnetic field forming means 205 and 305” if expressed in a general way. The cylindrical coils do not necessarily need to be shaped in the form of a cylinder or a coil. For example, the magnetic field can also be formed inside the processing chamber 201 by a permanent magnet.

Consider the situation in which the magnetic field is formed within the processing chamber, particularly, the corresponding discharge area in this way. It is generally easy for the plasma (discharge) to move or diffuse in the direction of the magnetic field (direction of magnetic field vector). It is adversely difficult for the plasma (discharge) to move or diffuse in the direction (perpendicular direction in particular) that intersects with the direction of the magnetic field (direction of magnetic field vector). In the prior art apparatus of FIG. 22 and the apparatus according to the present embodiment of FIG. 1, the surface of the sample 207 is placed so as to be approximately perpendicular to the direction of the magnetic field vector in consideration of the above. Namely, the vector of the normal to the surface of the sample 207 and the magnetic field vector thereof are placed so as to be approximately parallel. Described concretely, the direction of the central axis of the cylindrical coil 305 (the direction approximately coincident with the direction of the formed magnetic vector and the vertical direction as seen within the sheet in each of FIGS. 22 and 1, which is shown in the figure), and the direction of the vector of the normal to the surface of the sample 207 are placed so as to be parallel to each other. This is because the formed plasma can be made incident to the sample surface efficiently by doing so.

Now consider the prior art apparatus of FIG. 22 after becoming acquainted with such an arrangement. With the application of an RF bias, RF current flows between the sample 207 and the side wall (which serves as the ground potential electrode) of the processing chamber 201. At this time, part of the RF current path consequently crosses the magnetic field (magnetic field vector) substantially at right angles in the arrangement of the prior art apparatus of FIG. 22. This is because a line segment which connects the region of at least part of the sample surface and the side wall of the processing chamber 201, inevitably intersects with the direction of the magnetic field vector (approximately the direction of the central axis of the cylindrical coil 205). Generally, at a plasma in which a magnetic field is applied, the impedance (cross impedance) in the direction (the intersecting direction in general) crossing the magnetic field substantially at right angles becomes larger than the impedance in the direction approximately parallel to the magnetic field (magnetic field vector). Namely, when the RF current flows in the direction substantially normal to the magnetic field (magnetic field vector), a large voltage drop (change in potential) occurs. This phenomenon is called “cross impedance and voltage drop (change in potential) due to cross impedance”. Accordingly, in the arrangement of the prior art apparatus of FIG. 22, a large fluctuation (dependence of location in the sample surface) occurs in acceleration energy (kinetic energy) of each ion launched to the sample surface according to the location because of the voltage drop (change in potential) due to the cross impedance. This is because the resistance value (impedance) of a current path which connects the central area of the sample and the side wall of the processing chamber, and the resistance value (impedance) of a current path which connects the end edge area (outer peripheral area) of the sample and the side wall of the processing chamber are much different from each other. As a result, in-plane fluctuations occur in the etching characteristics or surface treatment or finishing characteristics. In particular, the voltage drop (change in potential) due to the cross impedance is great at the central area of the sample. Accordingly, the acceleration energy of each incident ion decreases greatly. Namely, the effect of application of the RF bias is reduced at the central area of the sample. Further, the potential of the plasma that contacts the sample surface fluctuates according to the location of the sample surface. As a result, the difference in potential (between the central area of the sample and its end edge area, for example) occurs within the sample. This results in the breakage of an electronic device formed in the sample surface. The occurrence of such in-plane fluctuations and changes in the characteristics in the etching apparatus or surface processing apparatus will degrade the process performance and reliability of the apparatus. The above problems become pronounced with an increase in the diameter of the sample.

Next consider the apparatus according to the first embodiment of the present invention. The present apparatus is different from the apparatus according to the prior art of FIG. 22 in that the transmission electrode 310 is disposed opposite to the sample 207, in other words, the sample placement surface of the sample table 206. Such an electrode arrangement is called “facing electrode arrangement”. Further, as described above, the transmission electrode layer 312 of the transmission electrode 310 is connected to the ground potential on the electric circuit basis, and the transmission electrode 310 functions as the ground potential electrode related to the RF current. This arrangement and function are enabled because the transmission electrode has the characteristics disclosed in the present invention. In the apparatus having this arrangement and function, the RF current flows between the sample 207 and the transmission electrode 310 as shown in FIG. 1. This is done because the current flows in such a manner that the resistance value (path impedance) of its path becomes small, i.e., its path length becomes short approximately. Accordingly, the RF current flows parallel to the direction (approximately the direction of the central axis of the cylindrical coil 305) of the magnetic field vector and at an approximately constant path length without depending on the location of the sample surface. As a result, as is apparent from FIG. 1, the resistance value (path impedance) of the path for the RF current becomes approximately constant without depending on the location of the sample surface. Further, no cross impedance occurs and the resistance value (path impedance) of the path for the RF current becomes small. Thus, the acceleration energy (kinetic energy) of each ion incident to the sample surface does not fluctuate according to the location and hence becomes approximately constant. Further, a voltage drop in the RF current path becomes also small. Accordingly, a reduction in the acceleration energy of each incident ion is small, and the application of the RF bias acts more effectively. In addition, the breakage of the electronic device in the sample surface due to the voltage drop (change in potential) developed due to the cross impedance does not occur either. As the above result, the process performance and reliability of the apparatus of the present invention shown in FIG. 1 increases greatly. The method of applying the RF bias under the facing electrode arrangement shown in the apparatus of the present invention is referred to as “facing electrode RF bias application method (or facing electrode RF bias method)”.

The “facing electrode arrangement” used in the above description can be defined as “the sample 207 and the transmission electrode 310 (or transmission electrode layer 312) are disposed opposite to each other in the usual meaning”. Further, if it is defined quantitatively, it can be defined like, for example, the following equations (3) through (6):

h_{d}≦adₛ (3)

a≦1 (4)

Δh_{d}≦bh_{d} (5)

b≦½ (6)

where
dₛ: diameter of the sample [m] or equivalent diameter of the sample,
h_{d}: mean value of heights of discharge areas [m] and mean value of distance between the opposed sample surface and surface of the transmission electrode (or the surface of the transmission electrode layer) at the sample surface,
a: allowable aspect ratio,
Δhₐ: value of variation in the discharge area height, value of variation in the distance between the opposed sample surface and surface of the transmission electrode (or the surface of the transmission electrode layer) at the sample surface, and difference between the maximum and minimum values of the distance at the sample surface (maximum value−minimum value), and
b: allowable variable ratio.

The equivalent diameter of the sample means the diameter of a circle having the same area as the sample when the circle is imagined where the sample is not necessarily shaped in a circular form. The conditions for the equations (3) and (4) are of conditions for allowing most of the RF current to flow between the sample 207 and the transmission electrode 310 and allowing no RF current to flow between the sample 207 and the side wall of the processing chamber 201. Although a=1 normally, it is necessary to set a to a=0.5 and a=0.1 where it is desired to more strictly limit the RF current to the side wall of the processing chamber 201. The conditions for the equations (5) and (6) are of conditions for allowing the RF current to flow at an approximately constant path length without depending upon the location of the sample surface, i.e., setting the resistance value (path impedance) of the path for the RF current to be approximately constant without depending on the location of the sample surface. Although b=½ normally, it is necessary to set b to b=0.1 and b=0.05 where it is desired to more strictly restrict the resistance value of the path for the RF current.

The value of the optimum discharge area height (mean value of heights of discharge areas) h_{d} differs according to the required type of chemical reaction (type of surface finishing or treatment). As to etching, the value of h_{d} may appropriately be of 50 mm or less or 100 mm to 200 mm upon etching of an oxide film (insulating film) such as silicon oxide or the like. This is because it is necessary to reduce the voltage of discharge space to thereby suppress the decomposition of a processing gas (etching gas) to the utmost. On the other hand, upon etching of an electrical conductor material film or electrical semiconductor material film such s a poly-Si film, a metal film or the like, the value of h_{d} may appropriately be of 50 mm or more or 100 mm to 200 mm. This is because it is necessary to increase the volume of discharge space to promote the decomposition of the processing gas (etching gas). Therefore, the apparatuses quite different from one another have heretofore been used separately upon etching of the oxide film (insulating film) and etching of the electrical conductor material film (or electrical semiconductor material film). On the other hand, the technology of the present invention is capable of controlling the value of h_{d} in a wide range. The same apparatus or technology using the present invention is capable of executing the oxide film (insulting film) etching and the etching of the electrical conductor material film (or electrical semiconductor material film). It is thus possible to comprehensively reduce the cost for the processing apparatus or the cost for the development of the apparatus.

As described above, the present invention has the effect that “in the plasma processing apparatus having the magnetic field forming means, the problem associated with the cross impedance or the voltage drop due to the cross impedance is solved by the technology of the present invention, and hence the process performance and reliability of the apparatus are greatly enhanced”, and the effect that “the sample and the transmission electrode (or transmission electrode layer) are placed in the facing electrode arrangement to thereby make the resistance value of the path for the RF current approximately constant without depending on the location of the sample surface, and hence the process performance and reliability of the plasma processing apparatus are greatly enhanced”.

The effect that “in the plasma processing apparatus having the magnetic field forming means, the problem associated with the cross impedance or the voltage drop due to the cross impedance is solved by the technology of the present invention, and the process performance and reliability of the apparatus are greatly enhanced” is not necessarily limited to the apparatus according to the embodiment shown in FIG. 1. It is apparent that this effect is generally brought about in the plasma processing apparatus having the magnetic field forming means. The effect that “the sample and the transmission electrode (or transmission electrode layer) are placed in the facing electrode arrangement to thereby make the resistance value of the path for the RF current approximately constant without depending on the location of the sample surface, and the process performance and reliability of the plasma processing apparatus are greatly enhanced” is not necessarily limited to the apparatus according to the first embodiment shown in FIG. 1 either. It is apparent that this effect is generally brought about in the plasma processing apparatus in which the sample and the transmission electrode (or transmission electrode layer) are placed in the facing electrode arrangement.

The characteristics of the first embodiment and the advantageous effects of the invention of the present application, which have been described above, will become more apparent where the sample diameter (diameter of sample) increases and reaches approximately 250 mm or more and 400 mm or more.

Next, the present inventors have examined diversely the desirable configuration of the transmission electrode for processing the sample in the high uniform manner even though the sample diameter is brought to a large diameter, for example, approximately 250 mm or more and 400 mm or more. The results thereof will be explained below.

### [Basic Configuration of Transmission Electrode]

The basic configuration of the transmission electrode according to the present invention will first be explained using FIGS. 2A through 8.

The problems (A) through (D) to be solved by the present invention have been described in the section of “SUMMARY OF THE INVENTION”. These problems arise due to the cause of (1) the window 203 for introduction of the discharge forming electromagnetic wave being comprised of the dielectric (electrical insulator) material (prior art apparatus having the configuration of FIG. 22) or (2) the discharge forming electromagnetic wave 202 propagating through the electrode-to-electrode space from the outside to the inside (prior art apparatus having the configuration of FIG. 23).

The most fundamental method for solving these problems is to introduce at least part of a discharge forming electromagnetic wave into its corresponding discharge area through a transmission electrode. The transmission electrode has the characteristics in which it acts like a dielectric (electrical insulator) for a discharge forming electromagnetic wave (whose frequency f_{pf} normally ranges from 0.01 GHz to 10 GHz) and acts like a material (i.e., electrical conductor or electrical semiconductor) having electrical conductivity (electrical conduction) for an RF bias electromagnetic wave (whose frequency f_{rb} normally ranges from 0.01 MHz to 100 MHz and f_{rb}<f_{pf}) or an electromagnetic wave (whose frequency fₚᵢ ranges approximately from fₚᵢ=2 MHz to 20 MHz) for ion plasma vibrations. Here, the term “transmission electrode behaves like the dielectric for the discharge forming electromagnetic wave” means the term “most of the discharge forming electromagnetic wave incident to the transmission electrode penetrates the transmission electrode”. The term “transmission electrode has the electrical conductivity for the RF bias electromagnetic wave or the electromagnetic wave for the ion plasma vibrations” means the term “transmission electrode layer of the transmission electrode allows current for the RF bias electromagnetic wave or the ion plasma vibration electromagnetic wave to flow into the transmission electrode layer or outside the transmission electrode layer with almost no occurrence of voltage drop (under the condition that the voltage of the voltage drop is sufficiently smaller than the amplitude voltage of an electromagnetic wave or a peak-to-peak voltage). A description will be made later of the case in which the transmission electrode is cable of having such characteristics by providing each slender-shaped slot opening area in the transmission electrode layer.

If the transmission electrode has such characteristics, the causes (1) and (2) of the above problems are solved. Thus, the manner of solutions to the above problems (A) through (D) will be described below using FIGS. 2A and 2B.

FIGS. 2A and 2B respectively show the basic configuration of the transmission electrode and its use state. The transmission electrode 310 takes the configuration in which the transmission electrode layer 312 and the electrode protection layer 313 are laid on the surface of the electrode substrate 311. As the way to lay down them, laminating, or a physical or chemical lamination or the like is possible. The electrode protection layer 313 is not necessarily required. It is however desirable that the electrode protection layer 313 is laid to prevent the transmission electrode layer 312 from being sputtered by discharge. The electrode substrate 311 is not necessarily required, but the electrode substrate 311 is laid to ensure the mechanical strength of the transmission electrode or set the transmission electrode to part of the vacuum wall.

The electrode substrate 311 is formed of a dielectric (electrical insulator). Described concretely, the electrode substrate 311 is formed of dielectrics (electrical insulators) of MgO (magnesium oxide), CaO (calcium oxide), SiO₂ (silicon oxide, quartz), Al₂O₃ (aluminum oxide, alumina), Y₂O₃ (yttrium oxide, yttria), MgF₂ (magnesium fluoride), CaF₂ (potassium fluoride), AlF₃ (aluminum fluoride), YF₃ (yttrium fluoride), etc. or a mixture of these.

The transmission electrode layer 312 is comprised of a material having electrical conductivity, i.e., an electrical conductor or an electrical semiconductor. Plural slot opening areas are formed in the transmission electrode layer 312. As the electrical conductor, there can be used, for example, any of metals such as Ti (titanium), Cr (chromium), Ni (nickel), Fe (ferrum), Al (aluminum), Cu (copper), Ag (argentum), Au (aurum), etc., or an alloy containing at least some of these, or a material containing at least some of these. As the electrical semiconductor, there can be used, for example, Si, SiC, C or a compound semiconductor, or a material in which these are doped with an impurity. The transmission electrode layer 312 can be laminated on the electrode substrate 311 by a deposition method, a plating method or a spray method. Alternatively, the transmission electrode layer 312 formed in advance can be fixed or secured onto the electrode substrate 311 by fixation using an adhesive agent or physical fixation.

The electrode protection layer 313 is formed of the dielectrics (electrical insulators) described in the section of the constituent material of the electrode substrate 311 or the mixture of these, or the electrical semiconductors described in the section of the constituent material of the transmission electrode layer 312 or the combination of these. The electrode protection layer 313 can be laminated over the transmission electrode layer 312 and the electrode substrate 311 by the deposition method or the spray method. Alternatively, the electrode protection layer 313 formed in advance can be fixed onto the transmission electrode layer 312 and the electrode substrate 311 by fixation using an adhesive agent or physical fixation.

The transmission electrode layer 312 may electrically be placed in a floating potential or may be connected to the ground potential on the electric circuit basis as shown in FIG. 2A. Alternatively, as shown in FIG. 2B, the transmission electrode layer 312 may be connected to its corresponding high frequency power supply 208 on the electric circuit basis. The high frequency power supply to which the transmission electrode layer is connected on the electric circuit basis in FIG. 2B, may be different from the high frequency power supply to which the sample table 206 is connected on the electric circuit basis, or may be the same. As shown in each of FIGS. 2A and 2B, at least part of the sample table 206 may be connected to the corresponding high frequency power supply on the electric circuit basis. Alternatively, although not shown in FIGS. 2A and 2B, at least part of the sample table 206 may be connected to the ground potential (earth potential) on the electric circuit basis. Further, at least part of the sample table 206 may electrically be placed in the floating potential.

As described above, the transmission electrode 310 has the characteristics in which it behaves like the dielectric (electrical insulator) for the discharge forming electromagnetic wave (whose frequency f_{pf} normally ranges from 0.01 GHz to 10 GHz). Namely, most of the discharge forming electromagnetic wave incident to the transmission electrode 310 penetrates the transmission electrode. As a result, the propagation of the discharge forming electromagnetic wave 202 through electrode-to-electrode space from the outside to the inside ((2) the state of the prior art apparatus of FIG. 23 and the cause of its problem) is eliminated, so that the discharge forming electromagnetic wave 202 penetrates the transmission electrode 310 and is directly introduced into its corresponding discharge area. Consequently, the problem (B) is solved.

The transmission electrode 310 has the characteristics in which it behaves like a material (i.e., electrical conductor or electrical semiconductor) having electrical conductivity for the electromagnetic wave (whose frequency fₚᵢ ranges approximately from fₚᵢ=2 MHz to 20 MHz) for ion plasma vibrations. Namely, the transmission electrode layer 312 of the transmission electrode 310 allows current for the ion plasma vibration electromagnetic wave to flow into the transmission electrode layer or outside the transmission electrode layer with almost no occurrence of voltage drop (under the condition that the voltage of the voltage drop is sufficiently smaller than the amplitude voltage of an electromagnetic wave or a peak-to-peak voltage thereof). Consequently, the problem (Al) is solved.

The transmission electrode 310 has the characteristics in which it acts like a material (i.e., electrical conductor or electrical semiconductor) having electrical conductivity for the RF bias electromagnetic wave (whose frequency f_{rb} normally ranges from 0.01 MHz to 100 MHz and f_{rb}<f_{pf}) Namely, the transmission electrode layer 312 of the transmission electrode 310 allows current for the RF bias electromagnetic wave to flow into the transmission electrode layer or outside the transmission electrode layer with almost no occurrence of voltage drop (under the condition that the voltage of the voltage drop is sufficiently smaller than the amplitude voltage of an electromagnetic wave or a peak-to-peak voltage thereof). Consequently, the problems (A2), (C) and (D) are solved.

Further, as described in the first embodiment, the present invention has the effect that “in the plasma processing apparatus having the magnetic field forming means, the problem of the cross impedance or the voltage drop (change in potential) due to the cross impedance is solved by the technology of the present invention, so that the process performance and reliability of the apparatus are greatly enhanced”, and the effect that “the sample and the transmission electrode (or transmission electrode layer) are placed in the facing electrode arrangement to thereby make the resistance value of the path for the RF current approximately constant without depending on the location of the sample surface, and hence the process performance and reliability of the plasma processing apparatus are greatly enhanced”.

[Slot Opening Areas at Transmission Electrode Layer and their Structures]

With the provision of slot opening areas in the transmission electrode layer 312, the transmission electrode 310 is able to have the characteristics in which it behaves like a dielectric (electrical insulator) for the discharge forming electromagnetic wave (whose frequency f_{pf} normally ranges from 0.01 GHz to 10 GHz). Namely, the provision of each slot opening area in the transmission electrode layer 312 makes it possible to cause most of the discharge forming electromagnetic wave incident to the transmission electrode 310 to pass through the transmission electrode. However, in order to cause the transmission electrode 310 or the transmission electrode layer 312 to be practically applied to the plasma processing apparatus, the structure of the slot opening area needs to satisfy a predetermined condition. A description will now be made of the conditions that the structure of such a slot opening area should satisfy.

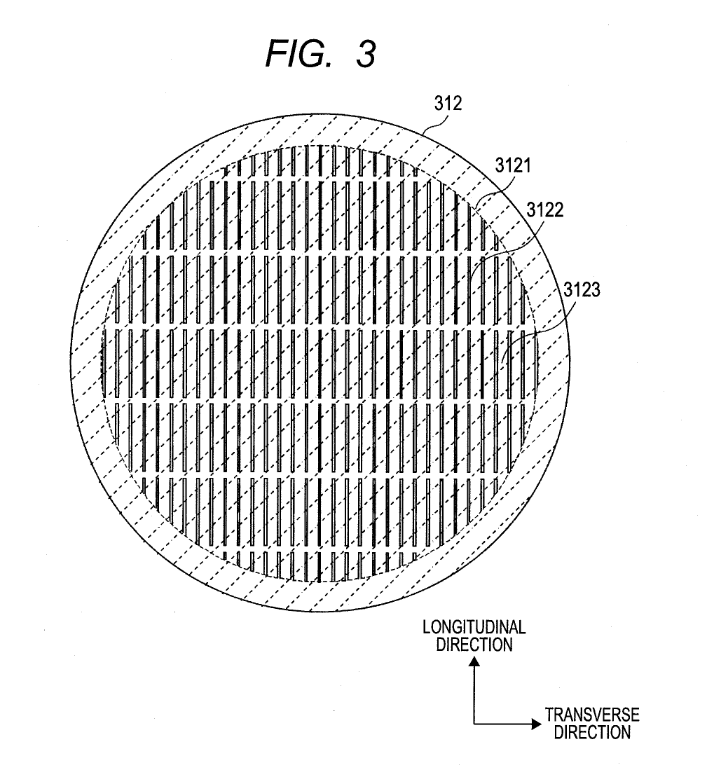

FIG. 3 is a plan view showing a structural example of each slot opening area in the transmission electrode layer. An electromagnetic wave transmission area 3121 exists within the transmission electrode layer 312. Plural slot opening areas 3122 are formed in the electromagnetic wave transmission area 3121. The electromagnetic wave transmission area 3121 need not necessarily be included inside the transmission electrode layer 312. The electromagnetic wave transmission area 3121 may be made equal to the whole area of the transmission electrode layer 312. The slot opening areas 3122 are of transmission electrode layer lacking areas each having a slender shape. The transmission electrode layer lacking areas (slot opening areas 3122) are of regions or areas at each which a material having electrical conductivity, forming the transmission electrode layer lacks in the transmission electrode layer.

Each slot opening area 3122 (transmission electrode layer lacking area) may be void or cavity areas (vacuum areas) free of the existence of a solid substance. The dielectric (electrical insulator) or the electrical semiconductor may be charged into the slot opening area 3122. Alternatively, the slot opening areas corresponding to the void areas (vacuum areas) and the slot opening areas charged with the above substance may be regarded as existent in mixed form. In the present example and the specification of the present application, the term “a given substance is charged into a given area” does not necessarily correspond to the term “substances lying in all areas in the given area are satisfied”, but also means the term “substances lying in at least part in the given area are satisfied”. Charging the above substance into each slot opening area 3122 makes it possible to prevent an abnormal discharge from occurring in this area. Setting the substance charged in the slot opening area 3122 to the substance equivalent to the electrode protection layer 313 or the electrode substrate 311 brings about an advantage of the transmission electrode 310 being easy to fabricate. This is because the substance charged in each slot opening area can be formed continuously or integrally with the material that forms the electrode protection layer or the electrode substrate. Charging the substance having adhesive performance between the electrode substrate 311 and the transmission electrode layer 312 or between the transmission electrode layer 312 and the electrode protection layer 313 is advantageous over the fabrication of the transmission electrode 310. This is because it becomes easy to bring the electrode substrate 311, the transmission electrode layer 312 and the electrode protection layer 3134 into integral form physically. In this case, the fabrication of the transmission electrode 310 can further be made easy by making the substance charged in the slot opening area equal to the substance having the adhesive performance. Since the substance having the adhesive property has even the characteristic low in degasification in vacuum, it is useful for suppressing the contamination of the sample surface. It is apparent that it is possible to use not only inorganic substances but also organic substances.

The direction parallel to the long side of the slender-shaped slot opening area 3122 is referred to as a longitudinal direction, and the direction perpendicular to the longitudinal direction is called a transverse or width direction. In the structural example of FIG. 3, the slot opening areas 3122 are periodically and repeatedly formed in the longitudinal and transverse directions.

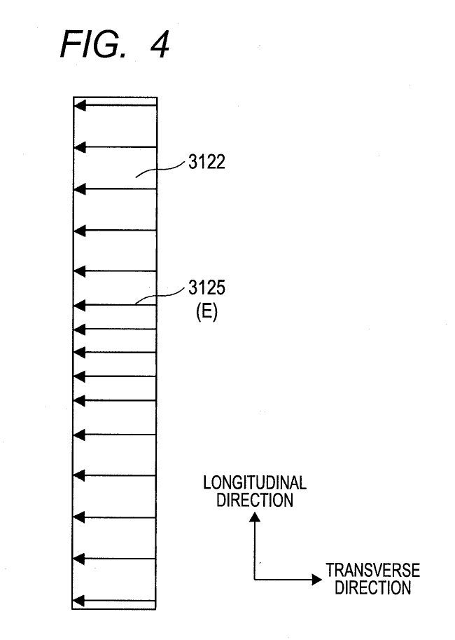

FIG. 4 is a diagram showing an electric field (E) in the slot opening area. The electric field 3125 is formed within the slot opening area 3122, and the direction of the electric field 3125 (direction of electric field vector) is parallel to the width direction. Accordingly, the electromagnetic wave having the electric field in the transverse direction by the discharge forming electromagnetic wave 302 incident to the transmission electrode layer 312, or part of the electromagnetic wave having the electric field in the transverse direction penetrates the transmission electrode layer 312 (or transmission electrode 310). Thus, when the path of propagation of the discharge forming electromagnetic wave 302 is designed, it is important that the main part of the discharge forming electromagnetic wave incident to the transmission electrode layer 312 is set to have the electric field parallel to the transverse direction of the slot opening area.

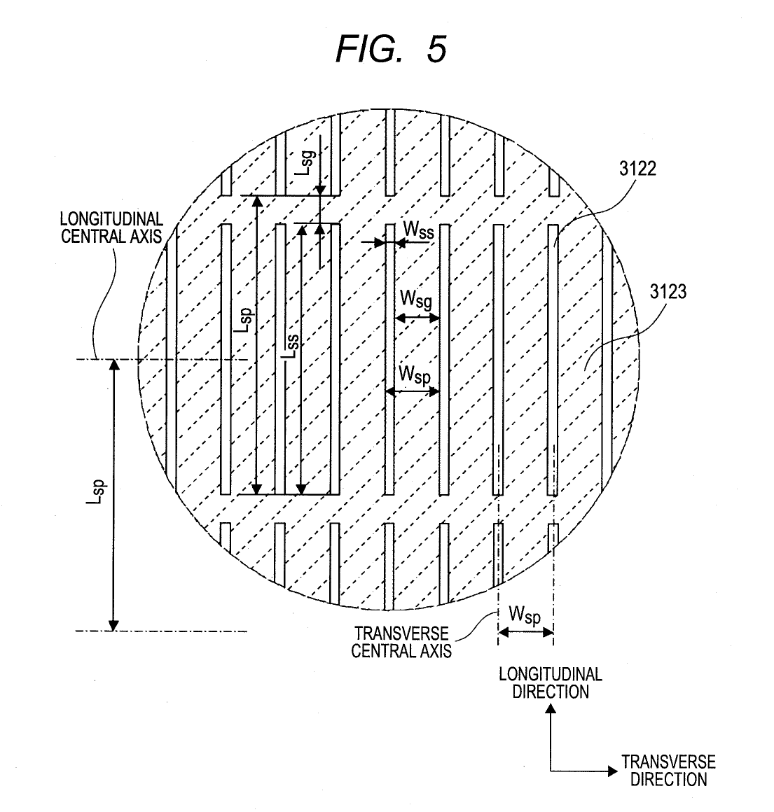

FIG. 5 is a partly enlarged view of the electromagnetic wave transmission area shown in FIG. 3. Structure constants in its longitudinal direction are as follows: When the length in the longitudinal direction of each slot opening area is assumed to be a slot opening length Lₛₛ, the distance between adjacent eng edges of slot opening areas adjacent to each other in the longitudinal direction is assumed to be a slot gap length L_{sg}, and Lₛₚ is assumed to be a slot period length, Lₛₚ satisfies a relationship expressed in the following equation (7):

Lₛₚ=Lₛₛ+L_{sg} (7)

The slot period length Lₛₚ can also be represented in the following manner. Namely, the axis used to divide each slot opening area approximately equally by the axis approximately parallel to the transverse direction of the slot opening area is referred to as a longitudinal central axis. The distance between the longitudinal central axes adjacent to each other corresponds to the slot period length Lₛₚ.

Structure constants in the transverse direction thereof are as follows: When the length in the transverse direction of each slot opening area is assumed to be a slot opening width Wₛₛ, the distance between adjacent end edges of the slot opening areas adjacent to each other in the transverse direction is assumed to be a slot gap width W_{sg}, and Wₛₚ is assumed to be a slot period width, Wₛₚ satisfies a relationship expressed in the following equation (8):

Wₛₚ=Wₛₛ+W_{sg} (8)

The slot period width Wₛₚ can also be represented in the following manner. Namely, the axis used to divide each slot opening area approximately equally by the axis approximately parallel to the longitudinal direction of the slot opening area is referred to as a transverse central axis. The distance between the transverse central axes adjacent to each other corresponds to the slot period width Wₛₚ.

Although the slot opening areas 3122 are rectangular in FIGS. 3, 4 and 5, the shape of the slot opening area 3122 need not necessarily be rectangular. It is needless to say that the slot opening area 3122 employed in the present invention can take an arbitrary slender shape. When the slot opening area 3122 takes an arbitrary slender shape, the structure numerical values of each slot opening area, such as the slot opening length Lₛₛ, slot gap length L_{sg}, slot period length Lₛₚ, slot opening width Wₛₛ, slot gap width W_{sg}, slot period width Wₛₚ, etc. are not necessarily defined distinctly. Even in this case, it is needless to say that the structure numerical values of each slot opening area can be defined by the mean value in the normal meaning within the slot opening area. The above is similar even in other drawings and texts of the present specification.

The term “slender-shaped slot opening areas (each having the slender shape)” used in the above description can be defined as the term “slot opening areas each having the slender shape in the normal meaning”. Further, if the content thereof is defined quantitatively, it can be defined as, for example, a slop opening area having the following characteristics. Namely, when Aₛ is assumed to be an aspect ratio of each slot opening area, As≧10 assuming that the following equation (9) is taken as Aₛ.

Aₛ=Lₛₛ/Wₛₛ (9)

Alternatively, Aₛ≧30, or more preferably Aₛ≧50, in order to make the slender shape more pronounced. Such a slender shape of each slot opening area is inevitably satisfied to enhance a transmission electrode layer transmission characteristic of a discharge forming electromagnetic wave to be described below, and the uniformity of the plasma processing characteristics.

In order to cause the discharge forming electromagnetic wave 302 to penetrate the transmission electrode layer 312 through each slot opening area 3122 with practical efficiency, the slot opening length Lₛₛ satisfies a relationship expressed in the following equation (10). It is desirably represented as follows:

Lₛₛ≧λ_{pf}_{_{—}}ₛ/2=A_{pf}_{_{—}}ₛλ_{pf}/2 (10)

where
λ_{pf}_{_{—}}ₛ: wavelength of the discharge forming electromagnetic wave at the slot opening area [m],
λ_{pf}: wavelength when the discharge forming electromagnetic wave propagates through the vacuum [m], and
A_{pf}_{_{—}}ₛ: wavelength correction coefficient at the slot opening area.
   Although the value of the wavelength correction coefficient A_{pf}_{_{—}}ₛ at the slot opening area is normally 1, the value thereof is 0.7 practically when the presence of the electrode substrate 311 and the electrode protection layer 313 is taken into consideration. λ_{pf} satisfies a relationship expressed in the following equation (11). Needless to say, it is represented as follows:

λ_{pf}=Cₚₜ/f_{pf} (11)

where
Cₚₜ: light velocity in vacuum [m/s], Cₚₜ=2.9979×10⁸ m/s, and
f_{pf}: frequency of the discharge forming electromagnetic wave [Hz]=[1/s].
   It is desirable that when f_{pf}=2.45 GHz, Lₛₛ>4.3 cm, and when f_{pf}=1 GHz, Lₛₛ>10.5 cm.

The above equation (10) is not an absolute necessary condition to cause the discharge forming electromagnetic wave to penetrate the transmission electrode layer through the corresponding slot opening area. Even when the equation (10) is not met, the penetration of the discharge forming electromagnetic wave through the transmission electrode layer is possible to a certain degree. The proportion of penetration of the discharge forming electromagnetic wave through the transmission electrode layer is however abruptly reduced according to the degree of dissatisfaction of the equation (10).

As to the fact that the discharge forming electromagnetic wave 302 penetrates the transmission electrode layer 312 through each slot opening area 3122, there is no principle restriction to the slot gap length L_{sg}. When, however, the slot gap length L_{sg} becomes extremely small, e.g., the slot gap length L_{sg} reaches 0.01 mm or less, the generation of heat by the discharge forming electromagnetic wave 302 at the corresponding slot gap portion occurs. Practically, the slot gap length L_{sg} is determined by ensuring of conductivity at the slot gap portion and processability (ease of processing). Described concretely, the value of the slot gap length L_{sg} may appropriately be in a range from 0.1 mm to 10 mm.

As to the fact that the discharge forming electromagnetic wave 302 penetrates the transmission electrode layer 312 through each slot opening area 3122, there is no principle restriction to the slot opening width Wₛₛ. When, however, the slot opening width Wₛₛ becomes extremely small, the electric field in the slot opening area 3122 becomes too strong, so that an abnormal discharge occurs in the vicinity of the slot opening area. When the slot opening width Wₛₛ becomes too large, ununiformity of the process characteristics at the sample surface occurs as mentioned in the section of discussions about the next slot period width Wₛₚ. Described specifically, the value of the slot opening width W, can appropriately be in a range of from 0.1 mm to 10 mm. Particularly when the uniformity of the process characteristics is important, the value thereof may appropriately be in a range of from 0.1 mm to 2 mm, further, 0.1 mm to 1 mm.

The lower limit value of the slot opening width Wₛₛ is however determined by the characteristics that the discharge forming electromagnetic wave 302 penetrates the transmission electrode layer 312 through each slot opening area 3122. Namely, the function of the present invention can be manifested even at values much smaller than the above values as shown below. A principle restriction relating to the characteristics of the penetration of the discharge forming electromagnetic wave through the transmission electrode layer is not imposed to the lower limit value.

When the value of the slot opening width Wₛₛ becomes, however, too small, the following electromagnetic disadvantages occur.

Namely, when the slot opening width Wₛₛ becomes too small to reach such an extent that mutually opposite atoms in atoms of a “material having electrical conductivity”, which exist in the outer periphery of the slot opening area 3122, produce electromagnetic interaction, the characteristics of the penetration of the discharge forming electromagnetic wave through the transmission electrode layer are abruptly degraded.

The lower limit value of the slot opening width Wₛₛ related to such a phenomenon is on the order of 100 nm (1×10⁻⁷m). When the slot opening width Wₛₛ becomes smaller than the thickness dₜₑ of the transmission electrode layer, the characteristics of the penetration of the discharge forming electromagnetic wave through the transmission electrode layer are gradually degraded. Namely, it is desirable that Wₛₛ>dₜₑ.

As will be described in the section of “thickness of transmission electrode layer” later, the practical lower limit of the thickness dₜₑ of the transmission electrode layer is 0.01 mm. Accordingly, the lower limit of the slot opening width Wₛₛ related to such a phenomenon is on the order of 0.01 mm.

It is appropriate from the above to set the lower and upper limits of the slot opening width Wₛₛ as shown below. The lower limit of the slot opening width Wₛₛ is 100 nm (1×10⁻⁷m) if an electromagnetic limit is taken into consideration. The lower limit thereof is 0.01 mm if the practical characteristics of penetration of the discharge forming electromagnetic wave through the transmission electrode layer are taken into consideration. The lower limit thereof is 0.1 mm if the reliability of the prevention of abnormal discharge or the like is taken into consideration. This means that if the limitation to each lower limit value, which is to be considered, is overcome, the function of the present patent can be manifested even at a smaller lower limit value. The upper limit of the slot opening width Wₛₛ is determined by the uniformity of the process characteristics at the sample surface, i.e., it is 10 mm. Particularly when the uniformity of the process characteristics is important, it is 2 mm and further 1 mm. These values are determined according to the degree of the practically required uniformity of process characteristics.

Regarding that the discharge forming electromagnetic wave 302 penetrates the transmission electrode layer 312 through each slot opening area 3122, there is no principle restriction to the slot period width Wₛₚ.

On the other hand, there is a need to meet the following practical conditions with respect to the slot period width Wₛₚ in order to apply the technology of the present invention to the plasma processing apparatus. Upon making this description, the area other than the slot opening areas 3122 at the transmission electrode layer 312 will be referred to as a non-slot opening area 3123. Since the discharge forming electromagnetic wave 302 is introduced into each discharge area through the slot opening area 3122, there is a possibility that a difference will occur between respective discharge characteristics (e.g., electron temperatures and electron densities) at the discharge area corresponding to each slot opening area and the discharge area corresponding to the non-slot opening area. The “discharge areas corresponding to the slot opening areas” means an area in which the majority of the discharge forming electromagnetic wave 302 having penetrated each slot opening area 3122 is absorbed by discharge, and a discharge area filled with the main part of a plasma generated in the corresponding area. On the other hand, the “discharge area corresponding to the non-slot opening area” is of a discharge area other than the “discharge area corresponding to each slot opening areas”. The “discharge area corresponding to the slot opening area” is referred to as a slot-based discharge area, and the “discharge area corresponding to the non-slot opening area” is referred to as a non-slot-based discharge area.

FIG. 6 is a diagram typically showing the process of allowing a discharge forming electromagnetic wave to pass through a transmission electrode layer to thereby absorb the same into each discharge area. The thickness dₑₛ of the electrode substrate, the thickness dₜₑ of the transmission electrode layer and the thickness dₑₚ of the electrode protection layer to be discussed later are also shown in FIG. 6. It is important for the plasma processing apparatus that the process characteristics become uniform at the sample surface. It is thus desirable that the vicinity of the sample surface is taken up by the slot-based discharge area alone. This is because when the slot-based discharge area and the non-slot-based discharge area exist in mixed form in the vicinity of the sample surface, ununiformity occurs in the discharge characteristic and hence ununiformity of the process characteristics at the sample surface occurs. To this end, it is desired that the slot period width Wₛₚ is smaller than the distance (absorption propagation distance) between the transmission electrode layer 312 (the surface on the discharge area side, of the transmission electrode layer) and the area in which the discharge forming electromagnetic wave 302 is absorbed. This is because the electromagnetic field of the discharge forming electromagnetic wave expands in the direction perpendicular to its propagation direction while the discharge forming electromagnetic wave is propagating over the absorption propagation distance, and a shadow portion of the electromagnetic field, which is formed by each non-slot-based opening area, disappears.

Though different according to the discharge conditions, the absorption propagation distance ranges from 10 mm to 100 mm. It is thus desirable that in order to enhance the uniformity of the process characteristics, the slot period width Wₛₚ is 100 mm or less, and further the slot period width Wₛₚ is 10 mm or less.

It is desirable that in order to further enhance the uniformity of the process characteristics, the slot period width Wₛₚ is smaller than the thickness dₑₚ of the electrode protection layer. This is because the electromagnetic field of the discharge forming electromagnetic wave expands in the direction perpendicular to its propagation direction while the discharge forming electromagnetic wave is propagating through the thickness dₑₚ of the electrode protection layer, and a shadow portion of the electromagnetic field, which is formed by each non-slot-based opening area, disappears. As mentioned in the section of “thickness of electrode protection layer” later, the thickness dₑₚ of the electrode protection layer is 10 mm or less or 1 mm or less. It is thus desirable that in order to further enhance the uniformity of the process characteristics, the slot period width Wₛₚ is 10 mm or less, and further the slot period width Wₛₚ is 5 mm or less, more preferably 1 mm or less. On the other hand, since Wₛₚ>Wₛₛ from the equation (8), the lower limit of Wₛₚ is determined by Wₛₛ.

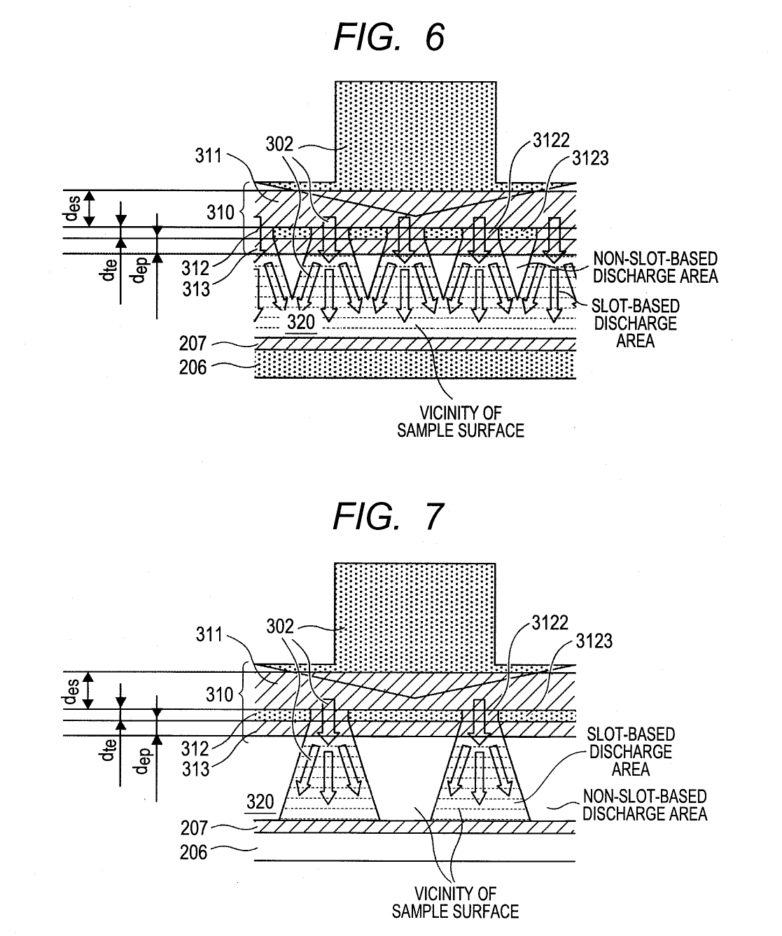

A comparative example is shown in FIG. 7. Namely, FIG. 7 typically shows the process of absorbing a discharge forming electromagnetic wave, similar to FIG. 6 where the slot period width Wₛₚ does not satisfy the “condition for enhancing the uniformity of the process characteristics” or the “condition for further enhancing the uniformity of the process characteristics”. In this case, a slot-based discharge area and a non-slot-based discharge area exist in mixed form in the vicinity of a sample surface. As a result, ununiformity occurs in the discharge characteristic and hence ununiformity of the process characteristics at the sample surface occurs.

Assume that the area of the electromagnetic wave transmission area 3121 is Sₜₜ and the sum of the areas of the slot opening areas existing in the electromagnetic wave transmission area is Sₛₛ. Rₛₜ=Sₛₛ/Sₜₜ is assumed to be a slot opening ratio. The slot opening ratio Rₛₜ is also Rₛₜ [symbol] WₛₛLₛₛ/(WₛₚLₛₚ). When the slot opening ratio Rₛₜ becomes extremely small, the electric field in each slot opening area 3122 becomes too strong, so that an abnormal discharge occurs in the vicinity of the slot opening area. In some cases, the electrode protection layer 313 may be destroyed. This is because the electric field in the slot opening area becomes strong with a reduction in the slot opening ratio Rₛₜ since a discharge forming electromagnetic wave having predetermined power (power necessary to form a discharge having a practical intensity) penetrates the corresponding transmission electrode layer. Practically, it is desirable that the slot opening ratio Rₛₜ is 0.01 or more and further the slot opening ratio Rₛₜ is 0.1 or mode to ensure safety.

[Need for Slender Shape in which Slot Opening Areas are Dense-Distributed]

The slot opening length Lₛₛ needs to meet the equation (10) in order to cause the discharge forming electromagnetic wave 302 to penetrate the transmission electrode layer 312 through each slot opening area 3122 with practical efficiency. On the other hand, it is necessary that in order to ensure the uniformity of the process characteristics at the sample surface, the slot opening length Lₛₛ, slot gap length L_{sg}, slot period length Lₛₚ, slot opening width Wₛₛ, slot gap width W_{sg} and slot period width Wₛₚ corresponding to the structure numerical values of the slot opening areas respectively satisfy the various conditions mentioned in the section of “slot opening areas at transmission electrode layer and their structures”, and the slot opening areas are dense-distributed within the transmission electrode layer.

As mentioned in relation to the solutions to the problems (A) through (D) up to now, it is necessary to realize the following characteristics. Namely, it is necessary that the RF current or current for the ion plasma vibration electromagnetic wave flows to the outside of the transmission electrode layer or the inside of the transmission electrode layer through the non-slot opening area 3123 of the transmission electrode layer 312. To this end, it is necessary that the non-slot opening area 3123 takes a singly-connected structure. Here, the term “area A being of singly-connected structure” means the term “two arbitrary points in the area A can be connected by a continuous curve”. In the embodiment of the transmission electrode layer shown in FIG. 3, the non-slot opening area 3123 is singly-connected in practice. This is similar even in other embodiments each illustrative of a transmission electrode layer to be descried subsequently.

In order to satisfy the above conditions, the slot opening areas 3122 inevitably have such slender shapes as to prevent the dense-distributed slot opening areas 3122 from being superimposed on each other.

### [Thickness of Transmission Electrode Layer]

First examine the condition under which the discharge forming electromagnetic wave 302 stably penetrates each slot opening area 3122. The upper limit of the thickness dₜₑ of the transmission electrode layer is determined from this examination. It is desirable that the standing wave of the discharge forming electromagnetic wave is not generated in the direction of thickness of the transmission electrode layer to cause the discharge forming electromagnetic wave to penetrate each slot opening area stably. To this end, it is desirable that the thickness dₜₑ of the transmission electrode layer is 1/10 or less of the wavelength λ_{pf} in vacuum of the discharge forming electromagnetic wave. It is desirable that when the frequency of the discharge forming electromagnetic wave is f_{pf}=2.45 GHz, for example, λ_{pf}=12 cm and dₜₑ<1.2 cm. It is desirable that in order to provide further stabilization, the thickness dₜₑ of the transmission electrode layer is 1/100 or less of the wavelength λ_{pf} in vacuum of the discharge forming electromagnetic wave. When the frequency of the discharge forming electromagnetic wave is f_{pf}=2.45 GHz, for example, dₜₑ<1.2 mm is desirable.

It is desirable that in order to cause the discharge forming electromagnetic wave to stably penetrate the slot opening area, the transmitted wave of the transmission electrode layer 312 (i.e., of each slot opening area 3122) and the waves reflected by the electrode substrate 311 and the electrode protection layer 313 do not interfere with each other. To this end, it is desirable that the thickness dₜₑ of the transmission electrode layer is smaller than the thickness dₑₛ of the electrode substrate and the thickness dₑₚ of the electrode protection layer. Since dₑₚ<dₑₛ in general, dₜₑ<dₑₚ is desirable. As will be described in the section of “thickness of electrode protection layer” later, the thickness dₑₚ of the electrode protection layer is 10 mm or less or 1 mm or less. It is thus desirable that the thickness dₜₑ of the transmission electrode layer is 10 mm or less and further the thickness dₜₑ of the transmission electrode layer is 1 mm or less.

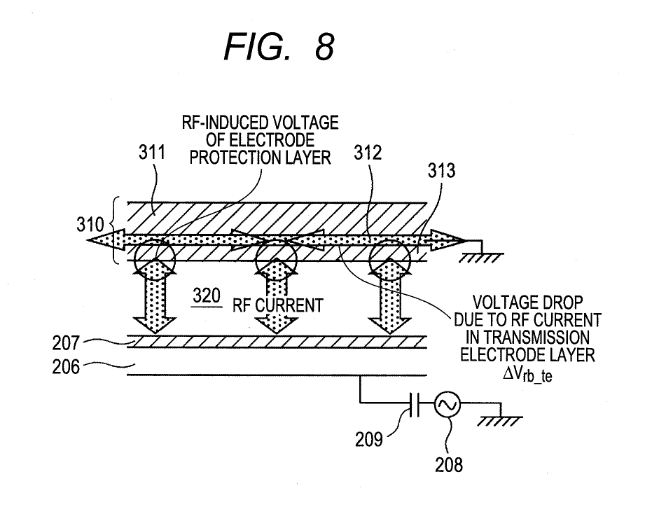

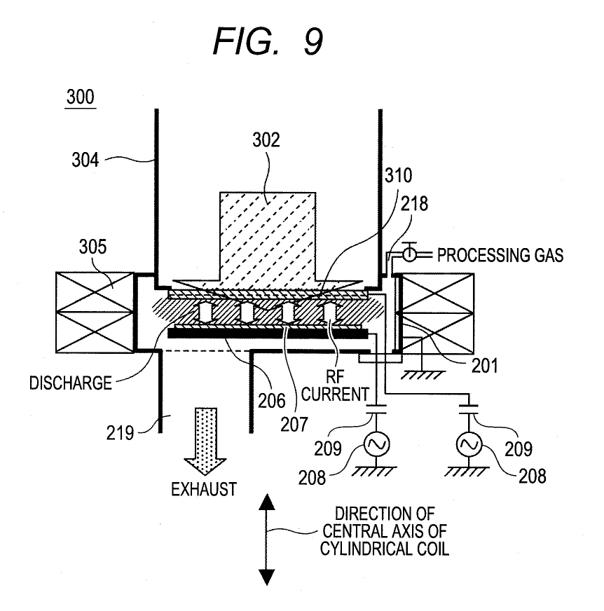

Next examine the condition for allowing RF current (current induced by RF bias electromagnetic wave) to stably flow within the transmission electrode layer. Namely, let's examine the phenomenon of a voltage drop developed due to the RF current at the transmission electrode layer. The lower limit of the thickness dₜₑ of the transmission electrode layer is determined from this examination. FIG. 8 typically shows the phenomenon of a voltage drop due to the RF current at the transmission electrode layer under the situation of FIG. 2A. A voltage generated by the voltage drop phenomenon is referred to as a drop voltage. While the voltage induced in the dielectric protection layer is also typically shown in FIG. 8, this will be discussed later in the section of “thickness of electrode protection layer”.

An RF drop voltage ΔV_{rb}_{_{—}}ₜₑ at the transmission electrode layer satisfies a relationship expressed in the following equation (12). It is established as follows:

ΔV_{rb}_{_{—}}ₜₑ=(ρₜₑiᵢₛ/(4dₜₑ))rₜₑ² (12)

where
ΔV_{rb}_{_{—}}ₜₑ: RF drop voltage at the transmission electrode layer [V], and drop voltage of RF bias electromagnetic wave potential (RF voltage) caused by RF current at the transmission electrode layer,
ρₜₑ: specific resistivity of the transmission electrode layer (specific electrical resistance) [Ωm], and specific resistivity of material forming the transmission electrode layer,
iᵢₛ: current density of ions incident to the surface of the transmission electrode (surface on the discharge area side) [A/m²], and current density of saturated ions to the surface of the transmission electrode (surface on the discharge area side),
dₜₑ: thickness of the transmission electrode layer [m], and
rₜₑ: radius of the transmission electrode layer [m] or equivalent radius of the transmission electrode layer.

The equation (12) determines a drop voltage between the central portion of the transmission electrode layer and its outer peripheral portion (end edge portion) assuming that the transmission electrode layer is in the form of a circle having a radius rₜₑ and ions are launched into its surface (surface on the discharge area side) at a uniform current density iᵢₛ. If, where the transmission electrode layer is not necessarily circular, a circle having the same area as that of the transmission electrode layer is assumed and its radius is called “the equivalent radius of the transmission electrode layer”, and rₜₑ is assumed to be equal to “the equivalent radius of the transmission electrode layer”, the above equation (12) is substantially established. Each slot opening area is formed in the transmission electrode layer and the specific resistivity ρₜₑ of the transmission electrode layer is not necessarily equal to the specific resistivity of the material that forms the transmission electrode layer. The specific resistivity ρₜₑ of the transmission electrode layer in the equation (12) means the mean value of specific resistivity at the whole transmission electrode layer.

As the standard condition for plasma processing, the saturated ion current density is assumed to be iᵢₛ=100 A/m² (=10 mA/cm²). The specific resistivity of the transmission electrode layer is assumed to be equal to the specific resistivity of Al (aluminum), and ρₜₑ is assumed to be equal to ρₜₑ=2.7×10⁻⁸ Ωm. A large diameter sample is considered and the radius of the transmission electrode layer is assumed to be rₜₑ=0.24 m (=240 mm). At this time, the equation (12) comes out like the following equation (13):

ΔV_{rb}_{_{—}}ₜₑ=4×10⁻⁸/dₜₑ (13)

When a peak-to-peak voltage (difference between an upper peak voltage and a lower peak voltage) of the RF bias electromagnetic wave is considered to normally range from 500 V to 2000 V, ΔV_{rb}_{_{—}}ₜₑ<10 V is required to uniformly apply the voltage of the RF bias electromagnetic wave to the transmission electrode layer. To this end, dₜₑ>4 nm is required from the equation (13). When it is desired to more uniformly apply the RF bias electromagnetic wave, ΔV_{rb}_{_{—}}ₜₑ<1 V is necessary and dₜₑ>40 nm is made necessary. Considering the diversity (e.g., the specific resistivity of Ti (titanium) is ρₜₑ=4.8×10⁻⁷ Ω/m) of the constituent material of the transmission electrode layer and also considering the generation of heat by the RF current, dₜₑ>10 nm, more preferably dₜₑ>100 nm are practically required.

Considering the above and also considering the ease of fabrication and the physical strength, it is practical that the thickness dₜₑ of the transmission electrode layer be in the range of 0.01 to 1 mm (dₜₑ=0.01 to 1 mm).

### [Thickness of Electrode Protection Layer]

Next discuss the thickness of the electrode protection layer. It is desirable that as described in FIG. 2, the surface of the transmission electrode layer 312 (the surface thereof on the discharge area side) is covered with its corresponding electrode protection layer 313. This electrode protection layer is formed by the dielectric (electrical insulator) or the semiconductor or by the combination of these. When the electrode protection layer is formed of the dielectric (electrical insulator), the electrode protection layer becomes charged due to the RF current (the incidence of charged particles such as ions or electrons) to the surface of the electrode protection layer from the discharge. The RF bias electromagnetic wave potential (RF voltage) applied to the transmission electrode layer by the above charge is modulated. It is desirable that this modulation is reduced to efficiently apply the RF voltage applied to the transmission electrode layer to the surface (discharge area-side surface) of the transmission electrode, i.e., the surface (discharge area-side surface) of the electrode protection layer. When the electrode protection layer is formed by either the semiconductor or the combination of the semiconductor and the dielectric, the influence of such a charge is reduced but still remains.

The voltage based on the modulation with the above charge is assumed to be an RF-induced voltage ΔV_{rb}_{_{—}}ₑₚ of the electrode protection layer. FIG. 8 typically shows the state of occurrence of the RF-induced voltage ΔV_{rb}_{_{—}}ₑₚ. The RF-induced voltage ΔV_{rb}_{_{—}}ₑₚ will be discussed below where the electrode protection layer is formed of the dielectric. This is done because the value of the RF-induced voltage ΔV_{rb}_{_{—}}ₑₚ becomes the largest in this case. The RF-induced voltage ΔV_{rb}_{_{—}}ₑₚ satisfies relationships expressed in the following equations (14) through (17). They are established as follows:

ΔV_{rb}_{_{—}}ₑₚ=Δqₑₚ/Cₑₚ (14)

Δqₑₚ=iᵢₛ(1/f_{rb})×0.9 (15)

Cₑₚ=∈ₑₚ/dₑₚ (16)

∈ₑₚ=kₑₚ∈₀ (17)

where
ΔV_{rb}_{_{—}}ₑₚ RF-induced voltage at the electrode protection layer [V] and amplitude of induced-voltage caused by the accumulation of RF-current charge at the electrode protection layer,
Δqₑₚ: storage charge density of the surface of the electrode protection layer [C/m²] and amplitude of density of charges stored in the surface of the electrode protection layer,
iᵢₛ: current density of ions incident to the surface of the transmission electrode (surface on the discharge area side) [A/m²] and current density of saturated ions to the surface of the transmission electrode (surface on the discharge area side),
Cₑₚ: capacity density of the electrode protection layer [F/m²],
f_{rb}: frequency of the RF bias electromagnetic wave [Hz=[1/s]],
∈ₑₚ: permittivity of the electrode protection layer [CV⁻¹ m⁻¹],
dₑₚ: thickness of the electrode protection layer [m]
∈₀: permittivity of vacuum [CV⁻¹ m⁻¹, ∈0=8.85×10⁻¹²CV⁻¹m⁻¹, and
kₑₚ: relative permittivity of the electrode protection layer and relative permittivity of material forming the electrode protection layer.

In the equation (15), the ions are assumed to be launched into the surface of the electrode protection layer during a period of 90%=0.9 of the period (1/fᵣₚ) of the RF bias electromagnetic wave. The value of 90% is of a value adequate under the normal RF bias application condition.

Assuming that as a representative condition, f_{rb}=13.56 MHz, iᵢₛ=100 A/m² (=10 mA/cm²), kₑₚ=4.5 (quarts (SiO₂) be assumed as the electrode protection layer material), and dₑₚ=1×10⁻³ m (=1 mm), ΔV_{rb}_{_{—}}ₑₚ=167 V. Assuming that as another representative condition, f_{rb}=13.56 MHz, iᵢₛ=10 A/m² (=1 mA/cm²), kₑₚ=4.5 (quarts (SiO₂) be assumed as the electrode protection layer material), and dₑₚ=1×10⁻² m (=10 mm), ΔV_{rb}_{_{—}}ₑₚ=167 V. Assuming that as a further representative condition, f_{rb}=13.56 MHz, iᵢₛ=10 A/m² (=1 mA/cm²), kₑₚ=4.5 (quarts (SiO₂) be assumed as the electrode protection layer material), and dₑₚ=1×10⁻³ m (=1 mm), ΔV_{rb}_{_{—}}ₑₚ=17 V. Considering that the peak-to-peak voltage (the difference between the upper peak voltage and the lower peak voltage) of the RF bias electromagnetic wave normally ranges from 500 V to 2000 V, these values of ΔV_{rb}_{_{—}}ₑₚ are values practically appropriate to apply the RF voltage to the sample table 206 and the sample 207. It is an apparatus condition that considering the above and also considering the diversity (e.g., the relative permittivity of yttria (Y₂O₃) is kₑₚ [symbol] 12) of the constituent material of the electrode protection layer, 10 mm or less (dₑₚ≦10 mm) is appropriate as the value of the thickness dₑₚ of the electrode protection layer. Further, it is another appropriate condition of apparatus that the thickness dₑₚ of the electrode protection layer is 1 mm or less (dₑₚ≦1 mm) to suppress ΔV_{rb}_{_{—}}ₑₚ lower.

On the other hand, the surface (surface on the discharge area side) of the electrode protection layer 313 is subjected to the discharge. The thickness dₑₚ of the electrode protection layer gradually decreases with the use of the apparatus by reaction with the discharge or discharge-based sputtering. It is a practical apparatus condition that in order to ensure a practical life span of the electrode protection layer, the thickness dₑₚ of the electrode protection layer is 0.001 mm or more (dₑₚ≧0.001 mm) or the thickness dₑₚ of the electrode protection layer is 0.01 mm or more (dₑₚ≧0.01 mm) and further the thickness dₑₚ of the electrode protection layer is 0.1 mm or more (dₑₚ≧0.1 mm). As the thickness dₑₚ of the electrode protection layer becomes larger, the practical life span of the electrode protection layer becomes longer.

Considering the above, it is practical that the thickness dₑₚ of the electrode protection layer be in the range of 0.1 to 10 mm (dₑₚ=0.1 to 10 mm).

### [Thickness of Electrode Substrate]

The thickness dₑₛ of the electrode substrate 311 will next be explained. When the electrode substrate 311 is designed so as to withstand the differential pressure between the atmospheric pressure and the pressure in the processing chamber by virtue of the transmission electrode 310 (when the transmission electrode 310 serves as a pressure wall), the electrode substrate 311 needs to withstand the differential pressure. In this case, the thickness of the electrode substrate 311 becomes large, and about 5 to 50 mm (dₑₛ=5 to 50 mm) is required under the normal (normal-size processing chamber) condition. On the other hand, when it is not necessary to withstand the differential pressure by virtue of the transmission electrode 310, it is appropriate that the thickness of the electrode substrate 311 be in the range of about 1 mm to 10 mm (dₑₛ=1 to 10 mm).

Incidentally, the transmission slits disclosed in JP Hei 6-104098 A are those related to the non-magnetic field plasma processing apparatus. Structure numerical values for defining the shapes of the transmission slits and their distribution have not completely been described. On the other hand, the present invention has manifested the concrete structure numerical-value conditions with which the dense-slot transmission electrode, i.e., slot opening areas 3122 for ensuring the practical plasma processing characteristics should be satisfied, based on the experimental and theoretical verifications. This has been mentioned in the section of “slot opening areas at the transmission electrode layer and their structures”.

Described concretely, there are the following differences between the technology disclosed in JP Hei 6-104098 A and the technology disclosed in the present invention. In FIG. 2(a) of JP Hei 6-104098 A, the rectangular transmission slits are formed in the rectangular-shaped “earthed electrode means”. If the aspect ratio Aₛ of the transmission slit is calculated in accordance with the definition of the present invention (present specification), Aₛ [symbol] 15. Assume that the standard wafer size (diameter of wafer) at that time (Heisei 4th year, 1992) that JP Hei 6-104098 A has been filed is 200 mm and the length of the short side of the rectangular-shaped “earthed electrode means” is equal to 1.5 times (300 mm) the value of 200 mm. The length thereof is set to 1.5 times the value thereof to ensure each area uniform in discharge characteristic in an area broader than the wafer size. Determining the slot opening width Wₛₛ and the slot period width Wₛₚ defined in the present invention (present specification) at this time yields Wₛₛ [symbol] 13 mm and Wₛₚ [symbol] 47 mm. While different depending on the process conditions (pressure of processing gas, power for introduction of discharge forming electromagnetic wave, discharge area heights, etc.), the transmission slits having such structure numerical values are not considered to have sufficient “dense” properties. Namely, it can be estimated that the process characteristics whose uniformity have been sufficiently ensured by the transmission slits of such structure numerical values have not been realized. At least the importance that the slot opening areas (transmission slits of JP Hei 6-104098 A are distributed in “dense” form has not discussed or examined in JP Hei 6-104098A.

The plasma processing apparatus having the magnetic field forming means has not been described at all in JP Hei 6-104098 A. On the other hand, it is apparent from the present invention that the following advantageous effects are brought about based on the experimental and theoretical investigations. Namely, in the plasma processing apparatus having the magnetic field forming means, the problem associated with the cross impedance or the voltage drop (change in potential) due to the cross impedance is solved by using the transmission electrode according to the technology of the present invention, thereby greatly enhancing the process characteristics and reliability of the apparatus.

### Second Embodiment

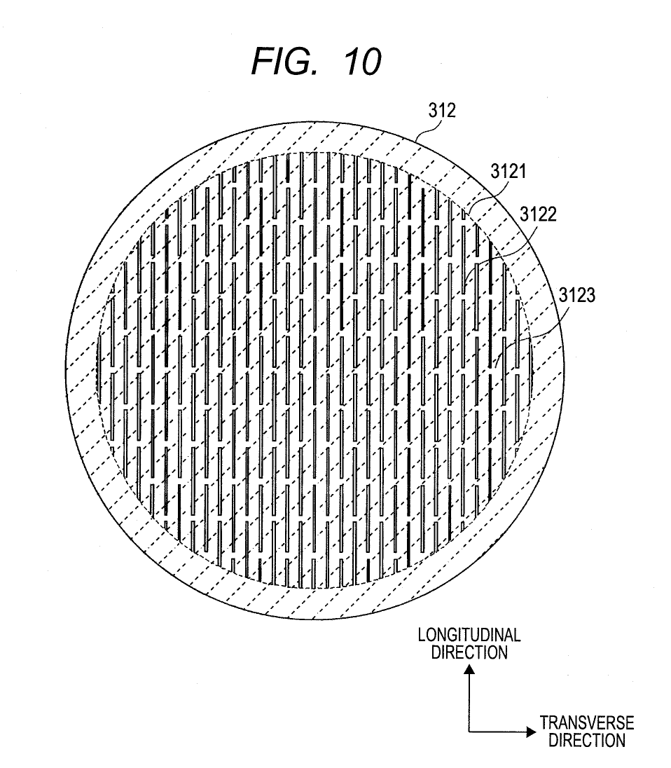

A plasma processing apparatus according to a second embodiment of the present invention will next be explained. FIG. 9 shows a longitudinal section of the plasma processing apparatus 300 according to the second embodiment of the present invention. Even in this example, a discharge forming electromagnetic wave 302 is supplied through a circular waveguide 304. A transmission electrode (or transmission electrode layer) 310 is provided between the circular waveguide 304 and a processing chamber 201. Further, the transmission electrode 310 and a sample placement surface of a sample table 206 lying in the processing chamber 201 are disposed opposite to each other. Thus, there is provided a facing electrode arrangement in which the transmission electrode 310 and a sample 207 are disposed opposite to each other. Magnetic field forming means 305 is disposed around the processing chamber 201.

The second embodiment is different from the first embodiment in that the transmission electrode layer 312 of the transmission electrode 310 is connected to a high frequency power supply 208 on an electric circuit basis in the second embodiment. The high frequency power supply to which the transmission electrode layer is connected on the electric circuit basis may be different from a high frequency power supply to which the sample table 206 is connected on the electric circuit basis or may be the same.

As to other points, the concrete configurations of the transmission electrode 310 and the like are identical to those described in relation to the first embodiment.

It is apparent that in a manner similar to the apparatus according to the first embodiment, the apparatus according to the second embodiment of the present invention also brings about the effect that “in the plasma processing apparatus having the magnetic field forming means, the problem associated with the cross impedance or the voltage drop (change in potential) due to the cross impedance is solved by the adoption of the corresponding transmission electrode, so that the process characteristics and reliability of the apparatus are greatly enhanced”, and the effect that “the sample and the transmission electrode (or transmission electrode layer) are placed in the facing electrode arrangement to thereby make the resistance value of the path for RF current approximately constant without depending on the location of the sample surface, thus greatly enhancing the process characteristics and reliability of the plasma processing apparatus”.

### Third Embodiment

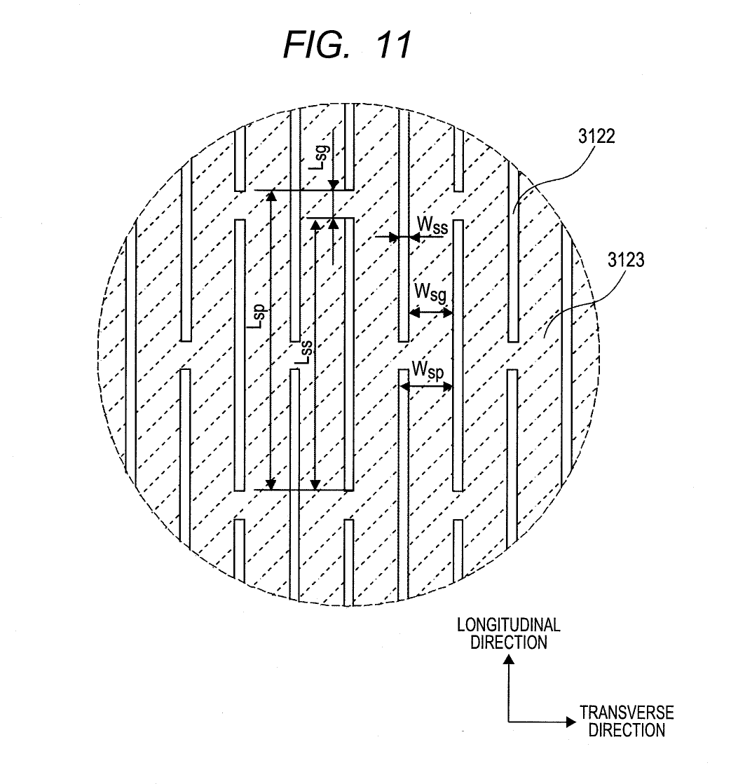

A plasma processing apparatus according to a third embodiment of the present invention will next be explained. FIG. 10 is a plan view showing a structural example of slot opening areas in a transmission electrode layer according to the third embodiment. FIG. 11 is a partly enlarged view of an electromagnetic wave transmission area in FIG. 10. The transmission electrode layer 312 is used in substitution with the transmission electrode layer 312 of the plasma processing apparatus 300 according to each of the first and second embodiments.

The structure of the transmission electrode layer according to the embodiment of the present invention shown in FIGS. 10 and 11 differs from the structure of the transmission electrode layer shown in FIGS. 3 through 8 in that the slot opening areas each adjacent in its transverse or width direction are shifted from each other by one half (½) of a slot period length Lₛₚ in its longitudinal direction. By doing so, the effects of the slot opening areas adjacent in the width direction and a non-slot opening area are spatially canceled out with one another, and the uniformity of a plasma formed and plasma processing characteristics can further be enhanced.

As to those other than the above point of difference, the structure of the transmission electrode layer according to the embodiment of the present invention and the condition with which the structure should be satisfied are identical to the structure of the transmission electrode layer shown in relation to FIGS. 3 through 8 and the first embodiment and the condition with which the structure should be satisfied. A method of measuring a slot opening length Lₛₛ, a slot gap length L_{sg}, a slot period length Lₛₚ, a slot opening width Wₛₛ, a slot gap width W_{sg} and a slot period width Wₛₚ indicative of structure numerical values for the transmission electrode layer according to the embodiment of the present invention is shown in FIG. 11.

### Fourth Embodiment

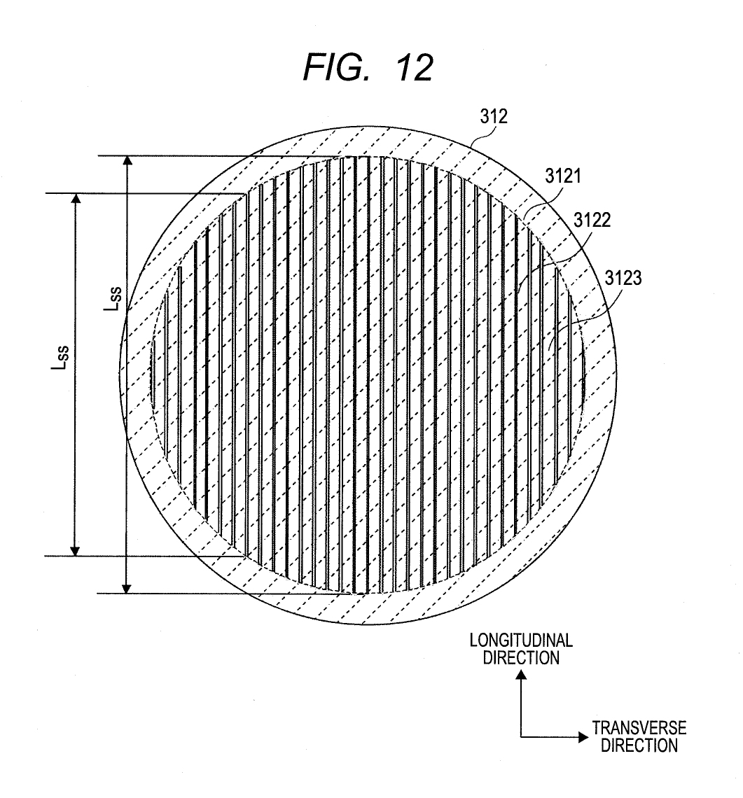

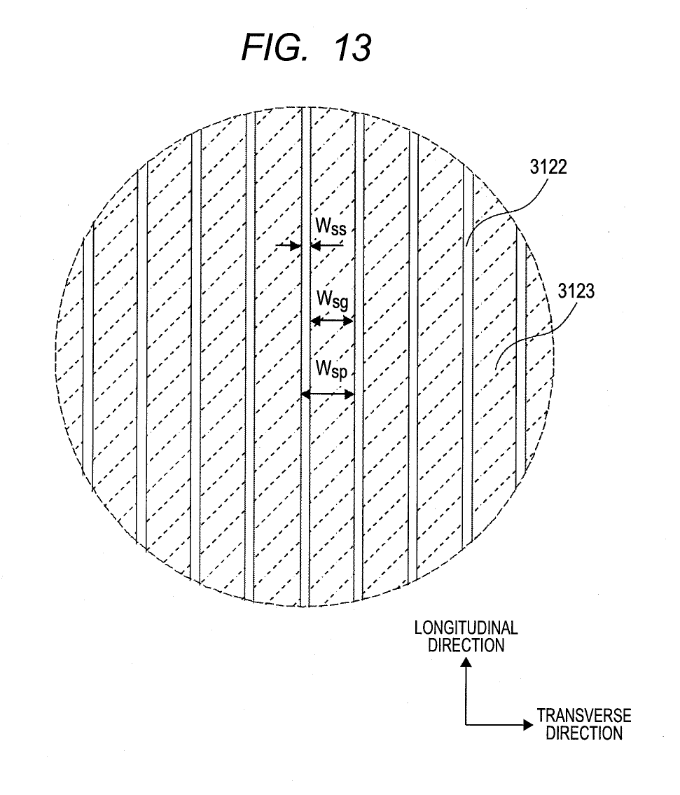

A plasma processing apparatus according to a fourth embodiment of the present invention will next be described. FIG. 12 is a plan view showing a structural example of slot opening areas in a transmission electrode layer according to the fourth embodiment. FIG. 13 is a partly enlarged view of an electromagnetic wave transmission area in FIG. 12. The transmission electrode layer 312 is used in substitution with the transmission electrode layer 312 of the plasma processing apparatus 300 according to each of the first and second embodiments.

The structure of the transmission electrode layer according to the embodiment of the present invention shown in FIGS. 12 and 13 differs from the structures of the transmission electrode layers shown in FIGS. 3 through 8 and FIGS. 10 and 11 in that the slot opening areas are continuous in the longitudinal direction within the electromagnetic wave transmission area 3121. Accordingly, their slot opening lengths Lₛₛ become values different depending on the locations in the width directions. In the structures of the transmission electrode layers according to the first embodiment (FIGS. 3 through 8) and the third embodiment (FIGS. 10 and 11), there was a possibility that the slot opening areas unsatisfying the condition of the equation (10) would be formed at the peripheral end edge portion of the electromagnetic wave transmission area 3121. There were therefore possibilities that the transmittance of the discharge forming electromagnetic wave 302 would be reduced at the peripheral end edge portion, and the electron density and temperature of each discharge area corresponding to the peripheral end edge portion would be lowered to thereby reduce the plasma processing speed. As a result, there was a possibility that the uniformity of the plasma processing characteristics at the sample surface would be degraded. On the other hand, at the transmission electrode layer according to the fourth embodiment (refer to FIGS. 12 and 13) of the present invention, the formation of the slot opening areas that do not satisfy the condition of the equation (10) is reduced to a minimum, and hence the uniformity of the characteristics of a formed plasma and that of the plasma processing characteristics of the sample surface are further improved. There is however a case in which since the slot opening areas extremely large in the slot opening length Lₛₛ are formed, a longitudinal standing wave of the discharge forming electromagnetic wave occurs in each of such slot opening areas so that the uniformity of the transmissivity of the discharge forming electromagnetic wave is generated. Whether any of the transmission electrode layers according to the first embodiment (FIGS. 3 through 8), the third embodiment (FIGS. 10 and 11) and the fourth embodiment (FIGS. 12 and 13) of the present invention should be used, differs according to the plasma processing characteristics for implementing the structure of the plasma processing apparatus. Alternatively, it is also possible to use a transmission electrode layer in which the structures of the above transmission electrode layers exist in mixed form.

As to those other than the above differences, the structure of the transmission electrode layer according to the embodiment of the present invention and the condition with which the structure thereof should be satisfied, are identical to the structure of the transmission electrode layer shown in relation to FIGS. 3 and 8 and the first embodiment and the condition with which the structure thereof should be satisfied. A method for measuring the slot opening length Lₛₛ, slot opening width Wₛₛ, slot gap width W_{sg} and slot period width Wₛₚ indicative of structure numerical values of the transmission electrode layer according to the embodiment of the present invention is shown in FIGS. 12 and 13.

### Fifth Embodiment

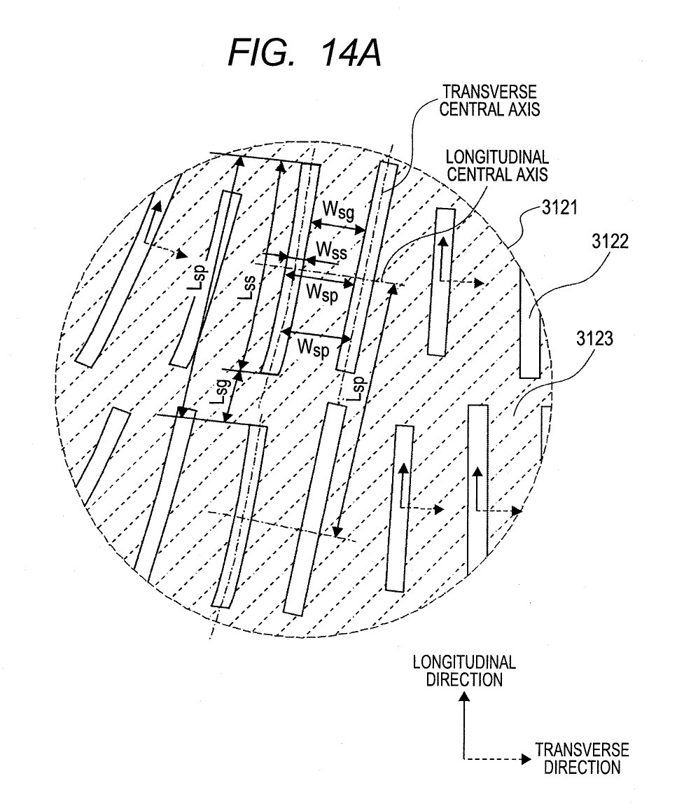

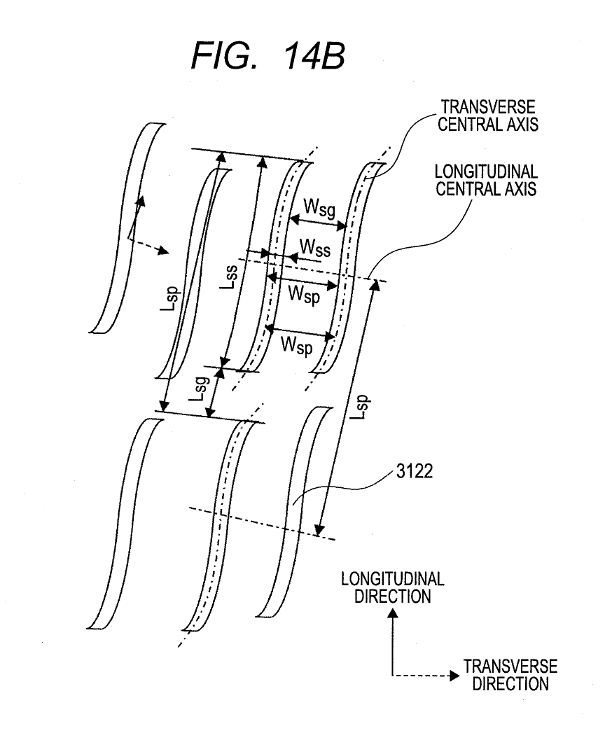

A plasma processing apparatus according to a fifth embodiment of the present invention will next be explained. FIGS. 14A is a partly enlarged view of an electromagnetic wave transmission area 3121 in a transmission electrode layer employed in the fifth embodiment. The transmission electrode layer 312 is implemented in substitution with the transmission electrode layer 312 of the plasma processing apparatus 300 according to each of the first and second embodiments.

In the present embodiment, there are distributed slot opening areas 3122 which are not necessarily identical to each other. The slot opening areas different in size, shape and tilt direction are distributed within the electromagnetic wave transmission area. Although not shown clearly in the drawing, the intervals between the slot opening areas adjacent to one another can also be distributed with being not necessarily identical within the electromagnetic wave transmission area. Even in such a case, the longitudinal direction, transverse or width direction, longitudinal central axis and transverse central axis of each individual slot opening area 3122 can locally be defined and measured by a method similar to one described up to now. A slot opening length Lₛₛ, a slot gap length L_{sg}, a slot period length Lₛₚ, a slot opening width Wₛₛ, a slot gap width W_{sg}, and a slot period width Wₛₚ indicative of structure numerical values of the slot opening areas can locally be defined and measured by a method similar to one described up to now. Such a defining/measuring method is shown in FIG. 14A. In FIG. 14A, there also exist slot opening areas whose transverse central axes are not necessarily linear in shape but curvilinear in shape. In the slot opening areas whose transverse central axes are made curvilinear in shape in this way, the longitudinal direction and the transverse direction differ according to the location within one slot opening area.

The shape of each slot opening area is not limited to the rectangular shape, but may be a substantially S-shaped opening whose width is approximately identical in its longitudinal direction as in an example of an electromagnetic wave transmission area shown in FIG. 14B. Alternatively, it may be an oblong-shaped opening. Even in either case, the shape of each slot opening area 3122 may be such one that each of the slot opening length Lₛₛ, slot gap length L_{sg}, slot period length Lₛₚ, slot opening width Wₛₛ, slot gap width W_{sg}, and slot period width Wₛₚ can locally be defined and measured as described in the example of FIG. 14A.

Distributing the slot opening areas 3122 having the various characteristics and structure numerical values within the transmission electrode layer 312 in this way makes it possible to locally control the transmittance of a discharge forming electromagnetic wave 302. It is thus possible to control a characteristic distribution of a formed plasma.

A concrete example of the fifth embodiment, a transmission electrode layer (transmission electrode) is provide in a circular waveguide, and the shape of each slot opening area for causing a discharge forming electromagnetic wave of a TE₁₁ mode for the circular waveguide to pass therethrough efficiently and uniformly, and its distribution will be described. Normally, a sample is circular and hence the cross-section (vacuum wall section) of a processing chamber employed in the plasma processing apparatus is also circular. It is therefore natural that the shape of the waveguide (formed by the wall of the processing chamber, or vacuum wall or their extended portions in many cases) at the position where the transmission electrode layer (transmission electrode) is placed, becomes also circular. It is thus important that various propagation modes of the circular waveguide for the discharge forming electromagnetic wave at the position of the transmission electrode layer (transmission electrode) should be taken into consideration. Considering the TE₁₁ mode corresponding to the basic mode (in which accordingly, an electromagnetic wave intensity distribution is most uniform) in particular is particularly important.

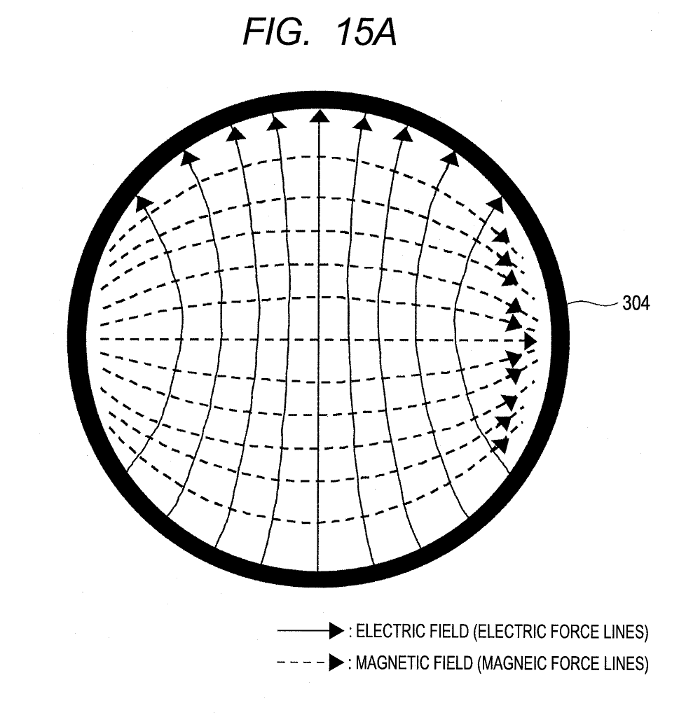

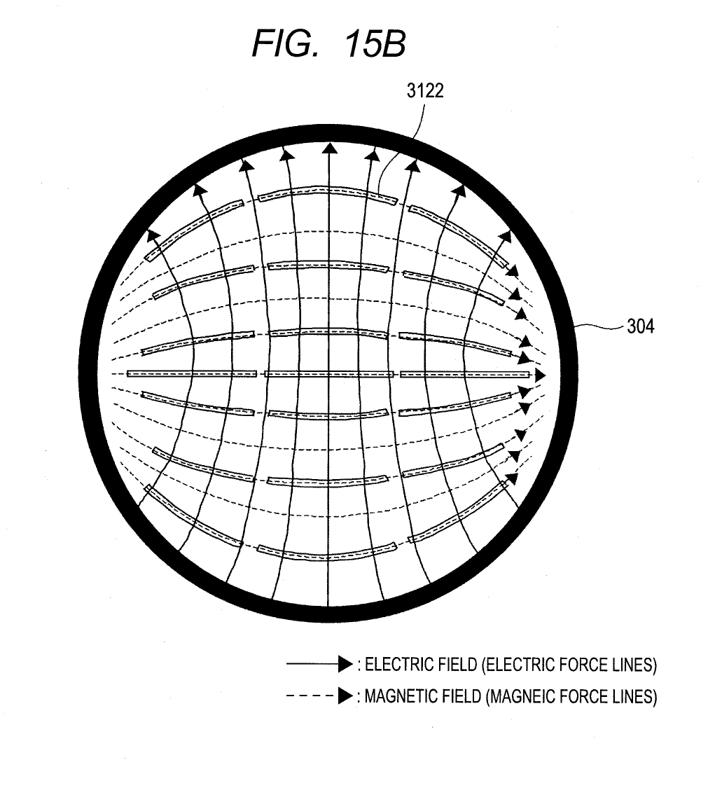

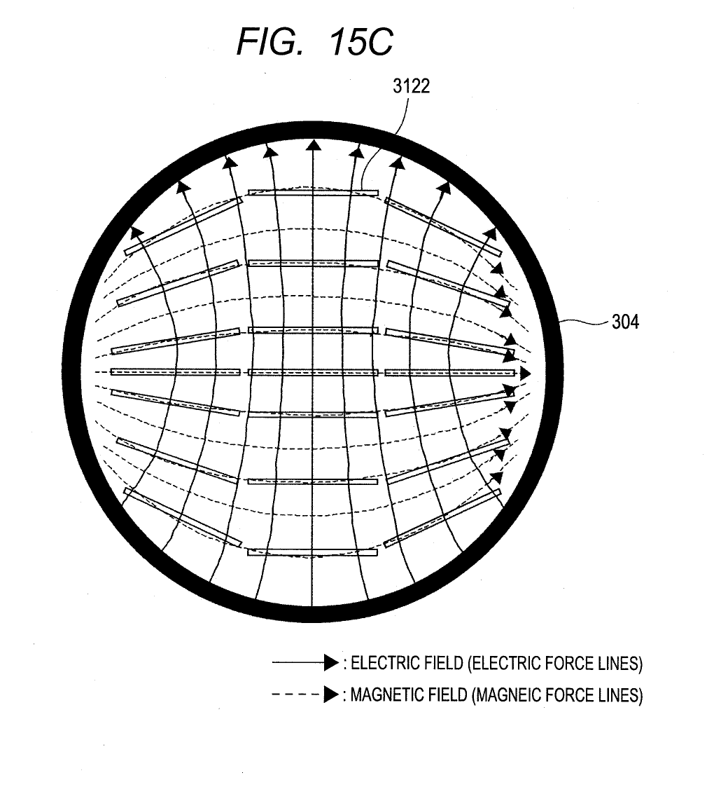

FIG. 15A is a diagram illustratively and typically showing parts of an electric field (lines of electric force) and a magnetic field (lines of magnetic force) in the TE₁₁ mode of the circular waveguide 304 at the position of the transmission electrode layer (transmission electrode). In the figure, the electric field (lines of electric force) is indicated by solid lines, and the magnetic field (lines of magnetic force) is indicated by broken lines. The TE₁₁ mode of the circular waveguide can freely be rotated in the circumferential direction of the circular waveguide. Namely, it is possible to freely set the circumferential rotational angle in the TE₁₁ mode. FIG. 15A shows the TE₁₁ mode when the circumferential rotational angle is fixed to a given value.

As described in FIG. 4, the electromagnetic wave having the electric field in its width direction (normal to its longitudinal direction) by the discharge forming electromagnetic wave 302 incident to the transmission electrode layer 312, or part of the electromagnetic wave having the electric field in the width direction penetrates the transmission electrode layer 312 (or transmission electrode 310). On the other hand, the electric field (lines of electric force) and the magnetic field (lines of magnetic force) are perpendicular to each other in FIG. 15A. Namely, each of the slot opening areas is formed in such a manner that the longitudinal direction of the slot opening area locally defined by the above-mentioned method becomes parallel to the direction of the magnetic field (lines of magnetic force) in the TE₁₁ mode of the circular waveguide at the corresponding location, thereby making it possible to cause the discharge forming electromagnetic wave of the circular waveguide TE₁₁ mode to pass therethrough efficiently and uniformly. Alternatively, when another expression is made although it is equivalent, each of the slot opening areas is formed in such a manner that the width or transverse direction of the slot opening area locally defined by the above method becomes parallel to the direction of the electric field (lines of electric force) in the circular waveguide TE₁₁ mode at the corresponding location, thereby making it possible to cause the discharge forming electromagnetic wave of the circular waveguide TE₁₁ mode to pass therethrough efficiently and uniformly. Consequently, efficient and high uniform surface processing can be realized.

In the above description, the term “the direction A of each locally defined slot opening area becomes parallel to the direction B in the circular waveguide TE₁₁ mode at the corresponding location” also means that the direction A locally defined within a predetermined slot opening area becomes parallel to the direction B at the local place and also means that the direction A defined on an average basis within a predetermined slot opening area becomes parallel to the average direction B at the corresponding location.

FIG. 15B shows the shapes of slot opening areas 3122 for causing a discharge forming electromagnetic wave of a circular waveguide TE₁₁ mode at a transmission electrode position to pass therethrough efficiently and uniformly, and an example of their arrangement. Some of the slot opening areas to be installed are illustratively and typically shown in the drawing. In FIG. 15B, the shape and layout of each of the slot opening areas 3122 are set in such a manner that the transverse direction defined locally within each slot opening area becomes parallel to the direction of the electric field (lines of electric force) at the local place in the circular waveguide TE₁₁ mode. Accordingly, the transverse central axes of some slot opening areas are curvilinear in shape at the slot opening areas.

FIG. 15C shows other shapes of slot opening areas for causing a discharge forming electromagnetic wave of a circular waveguide TE₁₁ mode at a transmission electrode position to pass therethrough efficiently and uniformly, and an example of their arrangement. Some of the slot opening areas to be installed are illustratively and typically shown in the drawing. In FIG. 15C, the shape and layout of each of the slot opening areas 3122 are set in such a manner that the transverse direction defined on the average basis within each slot opening area becomes parallel to the direction of the average electric field (lines of electric force) at the location in the circular waveguide TE₁₁ mode. In FIG. 15C, all the slot opening areas are rectangular and their central axes are linear in shape. When the embodiment shown in FIG. 15C is compared with the embodiment of FIG. 15B, manufacturing of each slot opening area becomes easy and low in cost. Further, the practical advantageous effect substantially equivalent to that of the embodiment of FIG. 15B can be realized.

In the above description, it is needless to say that the term “the direction A is parallel to the direction B” does not necessarily means only that the direction A is parallel to the direction B in a strict manner, but means that the direction A is approximately parallel to the direction B. This is because the object of the present invention can practically be satisfied by virtue of both being parallel.

It is needless to say that the term “circular waveguide” in the above description generally means not only a waveguide whose shape is strictly circular but also a waveguide whose shape is substantially circular. This is similar throughout the present specification.

The TE₁₁ mode of the circular waveguide has been descried in detail in the above “Microwave Engineering—Fundamentals and Principles” by Masamitsu Nakajima (Morikita Publishing Co., Ltd.), Tokyo, 1975, for example.

### Sixth Embodiment

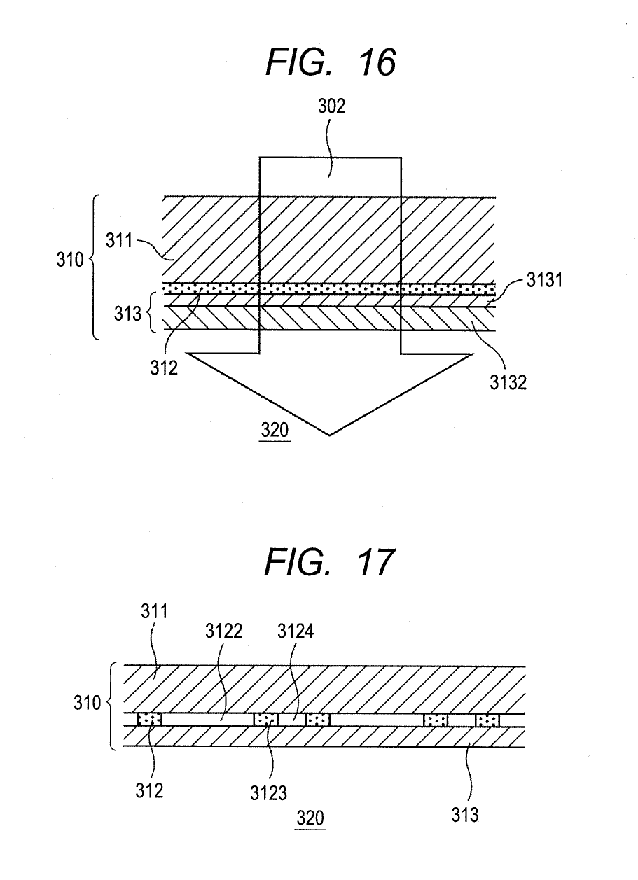

A plasma processing apparatus according to a sixth embodiment of the present invention will next be explained. FIG. 16 shows part of a cross-section of a transmission electrode 310. A discharge forming electromagnetic wave 302 (or part thereof) is supplied from the electrode substrate 311 side to a discharge area 320 through a transmission electrode layer 312 and an electrode protection layer 313. The transmission electrode 310 is implemented in substitution with the transmission electrode 310 of the plasma processing apparatus 300 according to each of the first and second embodiments.

The feature of the present invention resides in that the electrode protection layer has an electrode protection lower layer 3131 and an electrode protection upper layer 3132 as at least parts of constituent elements for the electrode protection layer. The electrode protection lower layer 3131 is formed on the surface of the transmission electrode layer 312 (surface on the discharge area side) in a laminated form, and the electrode protection upper layer 3132 is formed or located on the electrode protection layer 3131. As a method for forming the electrode protection layer 3131 in the laminated form, there is known, for example, the CVD (Chemical Vapor Deposition) method or the plasma CVD (Plasma Chemical Vapor Deposition) method. As a method of forming or placing the electrode protection layer 3132, there is known, for example, the CVD (Chemical Vapor Deposition) method, plasma CVD (Plasma Chemical Vapor Deposition) method, spray method, fixation using the adhesive agent, physical fixation or the like. The electrode protection layer 313 needs to be laid out in close adhesion to the transmission electrode layer 312 preferably in order to protect the transmission electrode layer 312. In order to ensure the life span of the transmission electrode 310, there is a need to lay out the electrode protection layer as thick as possible. However, the formation of the thick electrode protection layer in close adhesion to the transmission electrode layer normally involves technical difficulties. This is because internal stress occurs in the electrode protection layer and the electrode protection layer per se or the transmission electrode layer formed integrally with the electrode protection layer will be damaged. It is possible to overcome the technical difficulties by providing the structure for the isolation of the electrode protection layer from the electrode protection lower layer 3131 and the electrode protection upper layer 3132 as in the present embodiment.

How to strongly form the transmission electrode layer 312 on the electrode substrate 311 in the basis configuration of the transmission electrode of the present invention shown in each of FIGS. 2A and 2B and the sixth embodiment of the present invention shown in FIG. 16 is of an important subject. This is because there is a possibility that the transmission electrode is heated so that thermal stress occurs between the transmission electrode layer 312 and its corresponding electrode substrate 311. One method for solving this subject is to use a material strong in adhesion to the electrode substrate (normally formed of quartz, glass or alumina) as the material for the transmission electrode layer 312. W, Ti, Cr, Ni, or the like is excellent as such a material. Another method for solving the above subject is to roughen the surface of the electrode substrate 311 for forming the transmission electrode layer 312 in advance before the formation of the transmission electrode layer 312 (form concavo-convex or rugged shapes in the surface thereof). This is because the transmission electrode layer 312 can be stronger adhered to the electrode substrate 311 by roughening the surface of the electrode substrate 311. As a method for roughening the surface, there is known, for example, sand blasting. Making it less prone to generate the thermal stress between the transmission electrode layer 312 and the electrode substrate 311 is also effective as a fundamental solution method. Described concretely, a reduction in the difference in thermal expansion coefficient between the transmission electrode layer 312 and the electrode substrate 311 is effective. Providing a thermal expansion coefficient buffer layer for gradually changing the thermal expansion coefficient between the transmission electrode layer 312 and the electrode substrate 311 is also effective.

Thermal stress is similarly produced even between the transmission electrode layer 312 and the electrode protection lower layer 3131 employed in the embodiment of FIG. 16. Accordingly, a material excellent in adhesion to the transmission electrode layer 312 is suitable as the material for the electrode protection lower layer 3131. Silicon oxide (quartz, SiO₂), aluminum oxide (alumina, Al₂O₃) or yttrium oxide (yttria, Y₂O₃) is normally suitable therefor.

The function of the electrode protection layer 313 in the basic configuration of the transmission electrode shown in each of FIGS. 2A and 2B, and the electrode protection layer 3132 employed in the embodiment of FIG. 16 is to prevent the transmission electrode layer 312 from being sputtered by plasma. A dielectric like silicon oxide (quartz, SiO₂), alumina (Al₂O₃) or yttria (Y₂O₃) is suitable as the material for the electrode protection layer 313 or the electrode protection upper layer 3132 having such a function. Alternatively, there can also be used a semiconductor like silicon (Si), SiC, C or a compound semiconductor. The semiconductor may be doped with an impurity element. Alternatively, there can also be used a material in which a dielectric and a semiconductor are combined.

### Seventh Embodiment

A plasma processing apparatus according to a seventh embodiment of the present invention will next be explained. FIG. 17 shows part of a cross-section of a transmission electrode 310. A discharge forming electromagnetic wave 302 (or part thereof) is supplied from the electrode substrate 311 side to a discharge area 320 through a transmission electrode layer 312 and an electrode protection layer 313. The transmission electrode 310 is implemented in substitution with the transmission electrode 310 of the plasma processing apparatus 300 according to each of the first and second embodiments.

In the transmission electrode layer 312, an area other than slot opening areas 3122 is called a non-slot opening area 3123. The feature of the present invention resides in that a single or plural transmission electrode layer lacking areas are formed in at least part of the non-slot opening area 3123. Each transmission electrode layer lacking area in the non-slot opening area is called a second opening area 3124. The second opening area 3124 is of an area having an arbitrary shape, in which a material having electrical conductivity, forming a transmission electrode layer is lacked in the transmission electrode layer. For example, the shape thereof can take an arbitrary shape such as a circular shape, a rectangular shape, a line shape (slit shape, stria) or the like. The second opening area 3124 may be filled with a dielectric (electrical insulator) or may be placed in a cavity state or a vacuum state with no charging into the second opening area 3124.

The following practical advantageous effects can be realized by using the transmission electrode layer 312 according to the present embodiment. The size and shape of each individual second opening area 3124 is normally set so as to prevent the discharge forming electromagnetic wave 302 from passing therethrough. The second opening areas 3124 can be formed without the discharge forming electromagnetic wave 302 influencing the characteristic for penetration thereof through the transmission electrode layer 312. The second opening areas 3124 formed in this way can be made transparent. This is because it is easy to optically make transparent the dielectric (electrical insulator) forming the second opening area 3124, the cavity state or the vacuum state. It is thus possible to observe a state in a processing chamber through each second opening area 3124. It is also possible to observe the state in the processing chamber through each slot opening area 3122. It is, however, not necessarily possible to bring the shape and characteristic of the slot opening area 3122 into those suitable for the observation of the state in the processing chamber. In such a case, the observation in the processing chamber can be carried out in more detail by providing the second opening areas 3124 each of which can take an arbitrary shape.

### Eighth Embodiment

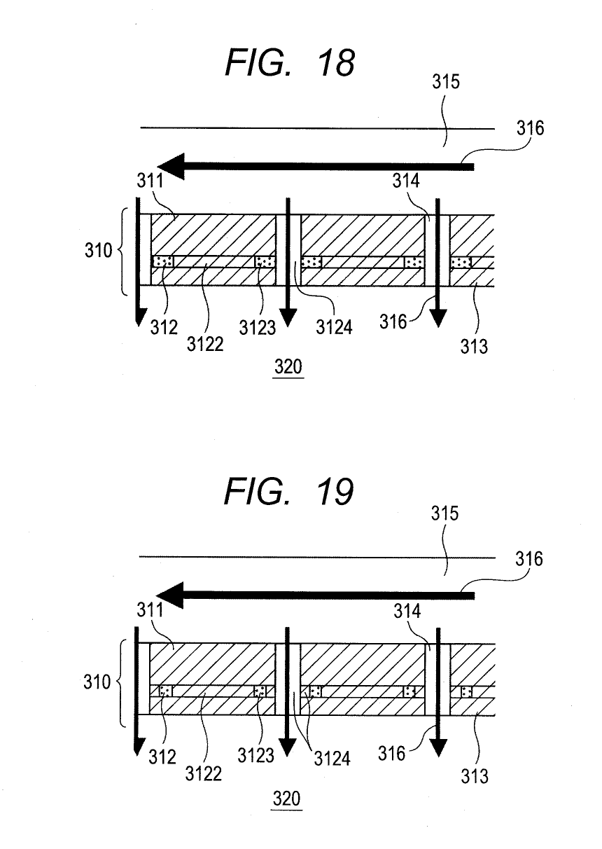

A plasma processing apparatus according to an eighth embodiment of the present invention will next be explained. FIG. 18 shows a transmission electrode 310 and part of a cross-section of its neighborhood. A discharge forming electromagnetic wave 302 (or part thereof) is supplied from the gas flow path chamber 315 side to a discharge area 320 through an electrode substrate 311, a transmission electrode layer 312 and an electrode protection layer 313. The transmission electrode 310 and the gas flow path chamber 315 are implemented in substitution with the transmission electrode 310 of the plasma processing apparatus 300 according to each of the first and second embodiments.

The features of the present embodiment include such a structure and function that at least part of an etching gas (also called processing gas) is introduced into a processing chamber 201 through each second opening area 3124. Described concretely, a gas blowout port 314 is formed in the transmission electrode 310 to connect the gas flow path chamber 315 provided on the upper side of the transmission electrode 310 to a processing gas supply port 218. When the electrode substrate 311 or the electrode protection layer 313 exist in the transmission electrode 310, the gas blowout port 314 is, as a matter of course, formed continuously so as to extend through the electrode substrate 311, the second opening area 3124 of the transmission electrode layer 312 and the electrode protection layer 313. Thus, the etching gas (or part thereof) is introduced into the processing chamber 201 through the processing gas supply port 218, the gas flow path chamber 315 and the gas blowout port 314 of the transmission electrode 310. A portion at which the gas blowout port 314 overlaps with the transmission electrode layer 312 serves as the second opening area 3124. In order to introduce the gas, the gas blowout port 314 (hence the second opening area 3124 that overlaps with the gas blowout port 314) is placed in a cavity state (cavity structure). Thus, the etching gas (or part thereof) is introduced into the processing chamber 201 through the gas flow path chamber 315 and the gas blowout port 314. A gas flow 316 shown in FIG. 18 typically show the flow of the etching gas. The structure and function of the present embodiment make it possible to uniformly the etching gas (or part thereof) into the processing chamber 201. Alternatively, it is possible to control a distribution of flow of the etching gas (or part thereof) into the processing chamber 201 by the structure and function of the present embodiment.

The etching gas (or part thereof) can also be introduced into the processing chamber 201 through the slot opening areas 3122. A strong electric field is however formed in each slot opening area 3122. There is therefore a possibility that when the etching gas (or part thereof) is supplied to the corresponding slot opening area, an abnormal discharge will occur in the same area. On the other hand, if the present embodiment is used, the electric field of the second opening area 3124 can sufficiently be weakened, and even though the etching gas (or part thereof) is supplied to the second opening area, no abnormal discharge is produced in the same area. This is because the electric field of the second opening area 3124 can sufficiently be weakened by making the opening size (maximum value of opening size) of the second opening area 3124 sufficiently smaller than a ½ wavelength (λ_{pf}/2) or A_{pf}_{_{—}}₅λ_{pf}/2 when the discharge forming electromagnetic wave propagates through vacuum.

Although the thickness of the electrode protection layer 314 is drawn to be smaller than the thickness of the electrode substrate 311 in FIG. 18, it is naturally possible to make the thickness of the electrode protection layer 313 so as to be larger than the thickness of the electrode substrate 311. Particularly, it is also possible to place the transmission electrode layer 312 and the electrode substrate 311 on the electrode protection layer 313 and make the thickness of the electrode protection layer 313 sufficiently large so as to withstand the entire load of these. By doing so, the manufacture and maintenance of the transmission electrode 310 can be facilitated. It is needless to say that such a structure can be applied to not only the present embodiment but also the general embodiments of the present invention.

Although the gas blowout port 314 is formed so as to overlap with (extend through) the electromagnetic wave transmission area 3121 of the transmission electrode layer 312 in the embodiment shown in FIG. 18, it is apparent that the gas blowout port 314 can also be formed in an area other than the electromagnetic wave transmission area 3121 of the transmission electrode layer 312. It is also apparent that the area of the transmission electrode 310 is partitioned to form the gas blowout port 314 and the transmission electrode layer 312 in different areas.

When the diameter (the size of opening of the gas blowout port; the diameter where its shape is circular) of the gas blowout port 314 becomes too small, a sufficient etching gas (processing gas) cannot be introduced into the processing chamber (or discharge area). On the other hand, when the diameter of the gas blowout port 314 becomes extremely large, there is a possibility that an abnormal discharge will occur inside the gas blowout port. The practical diameter of the gas blowout port 314 ranges from 0.1 mm to 1 mm.

### Ninth Embodiment

A plasma processing apparatus according to a ninth embodiment of the present invention will next be explained. FIG. 19 shows a transmission electrode 310 and part of a cross-section of its neighborhood. A discharge forming electromagnetic wave 302 (or part thereof) is supplied from the gas flow path chamber 315 side to a discharge area 320 through an electrode substrate 311, a transmission electrode layer 312 and an electrode protection layer 313. The transmission electrode 310 and the gas flow path chamber 315 are implemented in substitution with the transmission electrode 310 of the plasma processing apparatus 300 according to each of the first and second embodiments.

Although the present embodiment is basically equal to the eighth embodiment (FIG. 18), the present embodiment is different therefrom in the following points. In the eighth embodiment, the end face of the transmission electrode layer 312 directly appears inside the gas blowout port 314. Therefore, the end face of the transmission electrode layer comes into contact with a reactive gas formed by the etching gas (processing gas) or discharge, thus causing a possibility that this portion will be corroded. On the other hand, in the present embodiment (ninth embodiment and FIG. 19), the end face of the transmission electrode layer 312 does not appear directly inside the gas blowout port 314 and is covered with a dielectric (electrical insulator) or an electrical semiconductor. Namely, a second opening area formed with its corresponding gas blowout port is divided into two areas (areas denoted at two “3124” in the drawing). One of the two areas forms the gas blowout port 314, and the other thereof is filled with the dielectric (electrical insulator) or the electrical semiconductor. This charged material can be set to the same material as the electrode protection layer 313 or the electrode substrate 311. The fabrication of the transmission electrode 310 becomes easy by doing so.

### Tenth Embodiment

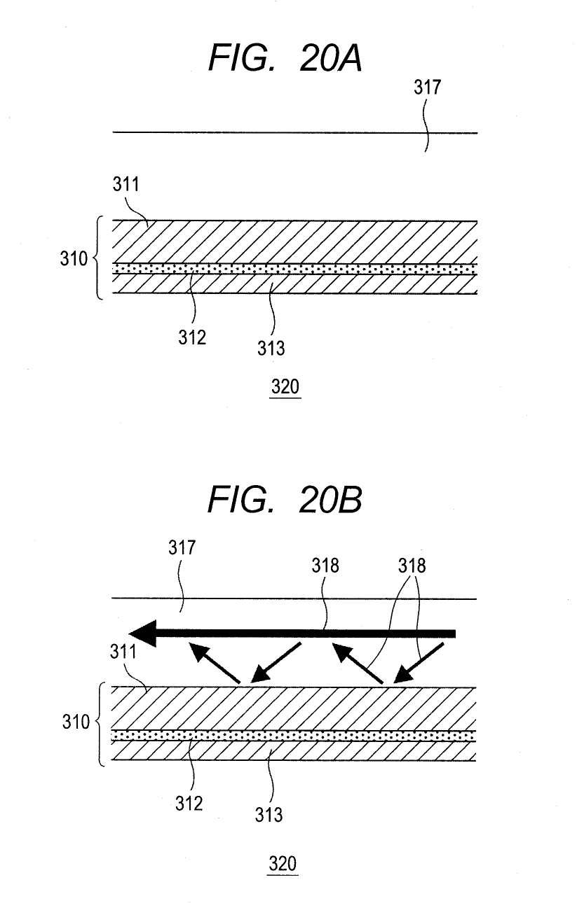

A plasma processing apparatus according to a tenth embodiment of the present invention will next be explained. FIG. 20A shows a transmission electrode 310 and part of a cross-section of its neighborhood. A discharge forming electromagnetic wave 302 (or part thereof) is supplied from the transmission electrode cooling means 317 side to a discharge area 320 through an electrode substrate 311, a transmission electrode layer 312 and an electrode protection layer 313. The transmission electrode 310 and the transmission electrode cooling means 317 are implemented in substitution with the transmission electrode 310 of the plasma processing apparatus 300 according to each of the first and second embodiments.

The features of the present embodiment include a facility or function to cool or temperature-control the transmission electrode 310. FIG. 20A typically shows a state in which the transmission electrode cooling means 317 is laid as the facility or function to cool the transmission electrode 310. FIG. 20B typically shows a state in which transmission electrode cooling means 217 having the function of cooling a transmission electrode by a coolant gas flow 318 is laid.

The facility and function of the present embodiment have the following practical advantageous effects. Since the transmission electrode layer 312 is formed of a material having electrical conductivity, part of the discharge forming electromagnetic wave 302 is absorbed into the transmission electrode layer 312. The generation of heat at the transmission electrode layer 312 due to RF current also occurs. As a result, the transmission electrode layer 312 and further the entire transmission electrode 310 are heated. The facility and function of the present embodiment can prevent the transmission electrode 310 from rising in temperature due to the above heating. Further, the facility and function of the present embodiment makes it possible to control the temperature of the transmission electrode 310. The temperature of the transmission electrode 310 can be controlled by, for example, controlling the flow rate of the coolant gas flow 318 or the temperature thereof. In this case, it is particularly effective that the function of measuring the temperature of the transmission electrode 310 is added and the flow rate or temperature of the coolant gas flow 318 is controlled using the result of measurement. Further, the control of the temperature of the transmission electrode 310 is important not only for a period (so-called processing time) during which plasma processing is simply being performed, but also for a period (so-called waiting time) taken between plasma processing and plasma processing. Executing such control makes it possible to enhance the reliability and stability of the apparatus and its processing.

### Eleventh Embodiment

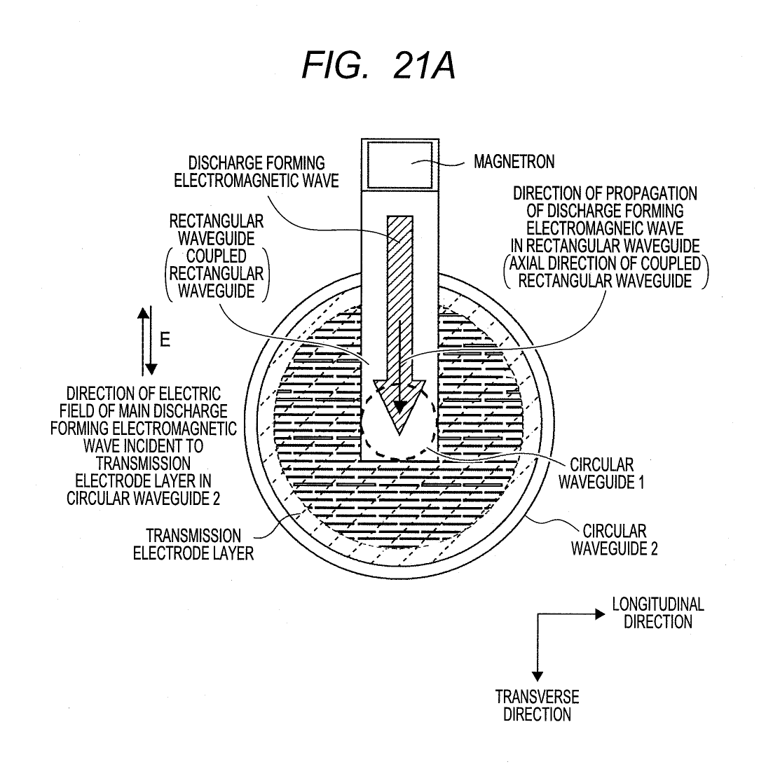

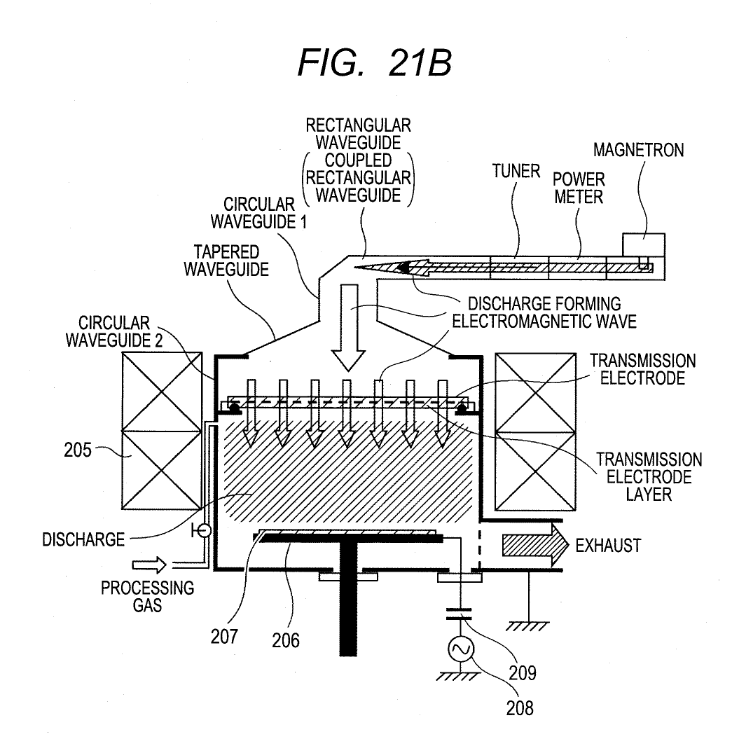

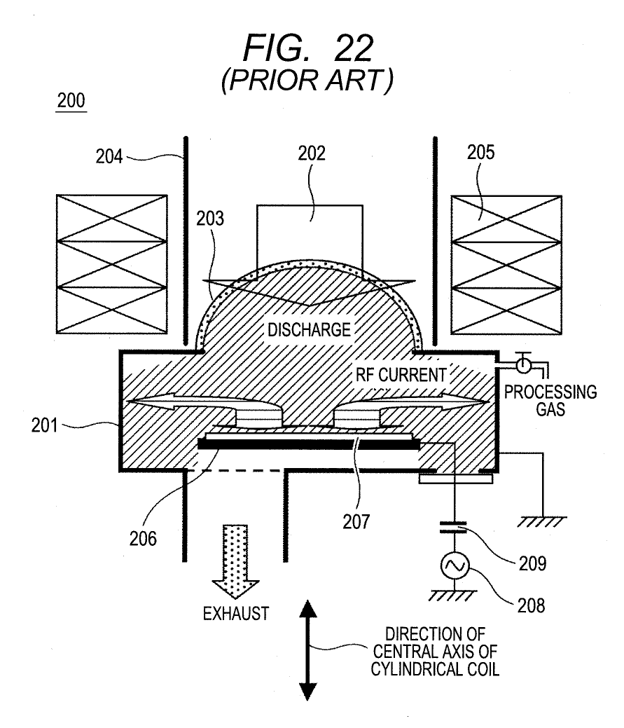

A plasma processing apparatus according to an eleventh embodiment of the present invention will next be described. FIG. 21A shows a relationship between a propagation path of a discharge forming electromagnetic wave, for introducing the discharge forming electromagnetic wave 302 into a processing chamber effectively, and the layout of a transmission electrode layer 312. In this case, it is important that as already described, the main part of the discharge forming electromagnetic wave incident to the transmission electrode layer is set so as to have an electric field parallel to the width or transverse direction (width direction of each slot opening area) of the transmission electrode layer.

Let's consider a structure wherein as shown in FIG. 21A, for example, the discharge forming electromagnetic wave is formed by a magnetron and propagates within a rectangular waveguide followed by introduction into a circular waveguide 1, after which the discharge forming electromagnetic wave is introduced into a circular waveguide 2. FIG. 21B is a diagram typically showing the side face of the apparatus shown in FIG. 21A. There is a case in which a tapered waveguide is installed between the circular waveguide 1 and the circular waveguide 2. In addition to it, there is also a case where the circular waveguide 1 and the circular waveguide 2 are directly coupled to each other. Alternatively, there is also a case in which the rectangular waveguide is directly coupled to the circular waveguide 2 without using the circular waveguide 1.

Further, assume that a transmission electrode layer (transmission electrode) is installed within the circular waveguide 2. Namely, the corresponding discharge forming electromagnetic wave is launched into the transmission electrode layer (transmission electrode) within the circular waveguide 2, and at least part of the discharge forming electromagnetic wave penetrates the transmission electrode layer, followed by being introduced into the processing chamber. In the above description, a vacuum wall of the processing chamber or its extended portion may form the circular waveguide 2.

Consider where in the above description, the rectangular waveguide includes plural parts having axial directions in directions different from one another. The term “rectangular waveguide” means a rectangular waveguide portion at the final stage (final stage on a traveling-wave propagation path of discharge forming electromagnetic wave), which is coupled indirectly or directly to the circular waveguide 2 as described above. This will be referred to as a coupled rectangular waveguide. The term “rectangular waveguide” means the coupled rectangular waveguide below.

In the case of such a structure, the direction of the electric field of the main discharge forming electromagnetic wave incident to the transmission electrode layer within the circular waveguide 2 becomes parallel to the direction of propagation of the discharge forming electromagnetic wave in the rectangular waveguide. The direction of propagation of the discharge forming electromagnetic wave in the rectangular waveguide is the same as the axial direction of the rectangular waveguide. It is thus important that when the above is taken into consideration, the axial direction (the direction of propagation of the discharge forming electromagnetic wave in the rectangular waveguide) of the rectangular waveguide is set parallel to the axial direction (the transverse direction of each slot opening area) of the transmission electrode layer in order to effectively introduce the discharge forming electromagnetic wave into the processing chamber.

When the shapes and directions of the slot opening areas are distributed in the transmission electrode layer, the transmission electrode layer (transmission electrode) is installed in such a manner that the mean transverse direction of each slot opening area in the transmission electrode layer or the local transverse direction of each slot opening area in the vicinity of the center of the transmission electrode layer becomes parallel to the axial direction (the direction of propagation of the discharge forming electromagnetic wave in the rectangular waveguide) of the rectangular waveguide. By doing so, the discharge forming electromagnetic wave can effectively be introduced into the processing chamber.

It is needless to say that the term “circular waveguide” in the above description generally means not only a waveguide whose shape is strictly circular, but also a waveguide whose shape is approximately circular. The term “rectangular waveguide” generally means not only a waveguide whose shape is strictly rectangular, but also a waveguide whose shape is approximately rectangular. They are similar throughout the present specification.

While the invention made above by the present inventors has been described specifically on the basis of the preferred embodiments, the present invention is not limited to the embodiments referred to above. It is needless to say that various changes can be made thereto within the scope not departing from the gist thereof.

What is claimed is:

1. A plasma processing apparatus for performing plasma processing, comprising:
a processing chamber;
means for introducing a processing gas into the processing chamber;
means for producing a discharge in at least partial areas in the processing chamber; and
means for holding a sample to be processed,
wherein each of the discharge-produced areas is provided as a discharge area,
wherein the plasma processing apparatus has magnetic field forming element for forming a magnetic field in at least partial area of the discharge areas,
wherein the plasma processing apparatus has element for introducing a discharge forming electromagnetic wave into the processing chamber, as at least part of the discharge producing means,
wherein the plasma processing apparatus has a transmission electrode for introducing at least part of the discharge forming electromagnetic wave into the corresponding discharge area,
wherein the plasma processing apparatus has a transmission electrode layer as at least part of constituent elements of the transmission electrode,
wherein the transmission electrode layer includes an electrical conductor or an electrical semiconductor corresponding to a material having electrical conductivity,
wherein the transmission electrode layer has an electromagnetic wave transmission area,
wherein a plurality of slot opening areas comprised of transmission electrode layer lacking areas each having a slender shape are formed in the electromagnetic wave transmission area,
wherein each of the slot opening areas is of an area in which the material having the electrical conductivity, forming the transmission electrode layer, is lacked in the transmission electrode layer,
wherein, when a direction parallel to a long side of the slot opening area is assumed to be a longitudinal direction, a direction perpendicular to the longitudinal direction thereof is assumed to be a transverse direction, a length of the slot opening area extending along the longitudinal direction thereof is assumed to be a slot opening length Lₛₛ, a length thereof extending along the transverse direction is assumed to be a slot opening width Wₛₛ, and Aₛ=Lₛₛ/Wₛₛ is assumed to be an aspect ratio of the slot opening area, the slot opening area whose slot opening width Wₛₛ ranges from 0.01 mm to 10 mm and whose aspect ratio Aₛ is 10 or more exists at least one,
wherein, when an axis which corresponds to an axis approximately parallel to the longitudinal direction of each of the slot opening areas and which divides each slot opening area approximately equally, is assumed to be a transverse central axis, a pair of the slot opening areas between which a slot period width Wₛₚ becomes 10 mm or less exist at least one, assuming a distance between transverse central axes adjacent to each other as the slot period width Wₛₚ, and
wherein, when the area of the electromagnetic wave transmission area is assumed to be Sₜₜ, the sum of the areas of the slot opening areas existing within the electromagnetic wave transmission area is assumed to be Sₛₛ, and Rₛₜ=Sₛₛ/Sₜₜ is assumed to be a slot opening ratio, the slot opening ratio Rₛₜ is 0.01 or more.

2. The plasma processing apparatus according to claim 1, wherein an electrical insulator or an electrical semiconductor is provided into at least part of the slot opening areas.

3. The plasma processing apparatus according to claim 1,
wherein a sample placement surface of the sample holding means and the transmission electrode or the transmission electrode layer are disposed opposite to each other,
wherein, when h_{d} is assumed to be a mean value of discharge area heights, a is assumed to be an allowable aspect ratio, dₛ is assumed to be a diameter or equivalent diameter of the sample, Δh_{d} is assumed to be a value of a variation in the discharge area height, and b is assumed to be an allowable variation ratio, h_{d} and Δh_{d} satisfy relationships expressed in the following equations (A3-1) and (A3-2):
h_{d}≦adₛ (A3-1)
Δh_{d}≦bh_{d} (A3-2),
and
wherein the allowable aspect ratio a=1, and the allowable variation ratio b=½.

4. The plasma processing apparatus according to claim 1, wherein the slot opening area whose slot opening width Wₛₛ ranges from 0.1 mm to 2 mm exists at least one.

5. The plasma processing apparatus according to claim 1, wherein the slot opening length Lₛₛ satisfies a relationship expressed in the following equation (A6-1):
Lₛₛ≧A_{pf}_{_{—}}ₛλ_{pf}/2 (A6-1)
where λ_{pf} indicates a wavelength when the discharge forming electromagnetic wave propagates through vacuum, and
wherein the slot opening area in which A_{pf}_{_{—}}ₛ=0.7 exists at least one.

6. The plasma processing apparatus according to claim 1,
wherein the transmission electrode is installed within a circular waveguide, and
wherein each of the slot opening areas is formed in such a manner that the locally-defined transverse direction of the slot opening area becomes parallel to the direction of an electric field in a TE₁₁ mode of the circular waveguide at a corresponding location.

7. The plasma processing apparatus according to claim 1,
wherein the transmission electrode is installed within a circular waveguide,
wherein a coupled rectangular waveguide indirectly or directly coupled to the circular waveguide is provided,
wherein the discharge forming electromagnetic wave sequentially propagates through the coupled rectangular waveguide and the circular waveguide and is launched into the transmission electrode, and
wherein the transmission electrode is installed in such a manner that the transverse direction of each of the slot opening areas, or the mean transverse direction of the slot opening area in the transmission electrode layer, or the local transverse direction of the slot opening area in the vicinity of the center of the transmission electrode layer becomes parallel to the axial direction of the coupled rectangular waveguide.

8. The plasma processing apparatus according to claim 1, wherein in the transmission electrode layer, a single or plural transmission electrode layer lacking areas are formed in at least part of a non-slot opening area corresponding to an area other than the slot opening areas,
wherein a second opening area corresponding to the transmission electrode layer lacking area in the non-slot opening area is of an area having an arbitrary shape, in which a material having electrical conductivity for forming the transmission electrode layer is lacked in the transmission electrode layer, and
wherein at least part of the processing gas is introduced into the processing chamber through the second opening area.

9. A plasma processing apparatus for performing plasma processing, comprising:
a processing chamber;
means for introducing a processing gas into the processing chamber;
means for producing a discharge in at least partial areas in the processing chamber; and
means for holding a sample to be processed,
wherein each of the discharge-produced areas is provided as a discharge area,
wherein the plasma processing apparatus has means for introducing a discharge forming electromagnetic wave into the processing chamber, as at least part of the discharge producing means,
wherein the plasma processing apparatus has a transmission electrode for introducing at least part of the discharge forming electromagnetic wave into the corresponding discharge area,
wherein the plasma processing apparatus has a transmission electrode layer as at least part of constituent elements of the transmission electrode,
wherein the transmission electrode layer includes an electrical conductor or an electrical semiconductor corresponding to a material having electrical conductivity,
wherein the transmission electrode layer has an electromagnetic wave transmission area,
wherein a plurality of slot opening areas comprised of transmission electrode layer lacking areas each having a slender shape are formed in the electromagnetic wave transmission area,
wherein each of the slot opening areas is of an area in which the material having the electrical conductivity, forming the transmission electrode layer, is lacked in the transmission electrode layer,
wherein, when a direction parallel to a long side of the slot opening area is assumed to be a longitudinal direction, a direction perpendicular to the longitudinal direction thereof is assumed to be a transverse direction, a length of the slot opening area extending along the longitudinal direction thereof is assumed to be a slot opening length Lₛₛ, a length thereof extending along the transverse direction thereof is assumed to be a slot opening width Wₛₛ, and Aₛ=Lₛₛ/Wₛₛ is assumed to be an aspect ratio of the slot opening area, the slot opening area whose slot opening width Wₛₛ ranges from 0.01 mm to 2 mm and whose aspect ratio Aₛ is 30 or more exists at least one,
wherein, when an axis which corresponds to an axis approximately parallel to the longitudinal direction of each of the slot opening areas and which divides each slot opening area approximately equally, is assumed to be a transverse central axis, a pair of the slot opening areas between which a slot period width Wₛₚ becomes 0.01 mm to 5 mm exists at least one, assuming a distance between transverse central axes adjacent to each other as the slot period width Wₛₚ, and
wherein, when the area of the electromagnetic wave transmission area is assumed to be Sₜₜ, the sum of the areas of the slot opening areas existing within the electromagnetic wave transmission area is assumed to be Sₛₛ, and Rₛₜ=Sₛₛ/Sₜₜ is assumed to be a slot opening ratio, the slot opening ratio Rₛₜ is 0.1 or more.

10. The plasma processing apparatus according to claim 9,
wherein the transmission electrode is installed within a circular waveguide, and
wherein each of the slot opening areas is formed in such a manner that the locally-defined transverse direction of the slot opening area becomes parallel to the direction of an electric field in a TE₁₁ mode of the circular waveguide at a corresponding location.
